(19) United States
(12) Patent Application Publication
(10) Pub. No.: US 2014/0363984 A1
(43) Pub. Date: Dec. 11, 2014

(54) MANUFACTURING METHOD OF SEMICONDUCTOR DEVICE

(71) Applicant: FUJITSU SEMICONDUCTOR LIMITED, Yokohama-shi (JP)

(72) Inventor: Masatoshi Fukuda, Akiruno (JP)

(73) Assignee: FUJITSU SEMICONDUCTOR LIMITED, Yokohama-shi (JP)

(21) Appl. No.: 14/285,781

(22) Filed: May 23, 2014

(30) Foreign Application Priority Data
Jun. 10, 2013 (JP) 2013-122016

(51) Int. Cl. H01L 21/033

(52) U.S. Cl. CPC H01L 21/033
USPC 438/778

(57) ABSTRACT

A manufacturing method of a semiconductor device includes forming a first resist film above a substrate, placing a first photomask, that includes a first mask pattern, in a first position above the first resist film, transferring the first mask pattern to the first resist film to form a first resist pattern above the substrate, forming a second resist film above the substrate after forming the first resist pattern, placing the first photomask in a second position above the second resist film, and transferring the first mask pattern to the second resist film to form a second resist pattern above the substrate.

### CROSS-REFERENCE TO RELATED APPLICATIONS

This application is based upon and claims the benefit of prior Japanese Patent Application No. 2013-122016 filed on Jun. 10, 2013, the entire contents of which are incorporated herein by reference.

### FIELD

The embodiments herein relate to a manufacturing method of a semiconductor device.

### BACKGROUND

A semiconductor integrated circuit is manufactured by forming a resist pattern on a substrate using a photomask (reticle) and forming semiconductor elements on the substrate using the resist pattern. Along with the miniaturization of semiconductor integrated circuits, there has been a demand to develop a technique of high-resolution exposure. For example, a fine resist pattern is formed on a substrate with an exposure apparatus, such as an immersion exposure apparatus or an EUV (Extreme Ultra Violet) exposure apparatus, using a multi-exposure technique. As exposure technology advances, there is a demand to increase the accuracy of the mask patterns of a photomask.

[Patent document 1] Japanese Laid-open Patent Publication No. 2004-86097

### SUMMARY

According to an aspect of the embodiments, a manufacturing method of a semiconductor device includes, forming a first resist film above a substrate, placing a first photomask, that includes a first mask pattern, in a first position above the first resist film, transferring the first mask pattern to the first resist film to form a first resist pattern above the substrate, forming a second resist film above the substrate after forming the first resist pattern, placing the first photomask in a second position above the second resist film, and transferring the first mask pattern to the second resist film to form a second resist pattern above the substrate.

The object and advantages of the embodiments will be realized and attained by means of the elements and combinations particularly pointed out in the claims. It is to be understood that both the foregoing general description and the following detailed description are exemplary and explanatory and are not restrictive of the embodiments, as claimed.

### BRIEF DESCRIPTION OF THE DRAWINGS

FIG. 1A is a plan view illustrating a manufacturing method of a semiconductor device according to an embodiment 1;

FIG. 1B is a cross-sectional view illustrating the manufacturing method of the semiconductor device according to the embodiment 1;

FIG. 2A is a plan view illustrating the manufacturing method of the semiconductor device according to the embodiment 1;

FIG. 2B is a cross-sectional view illustrating the manufacturing method of the semiconductor device according to the embodiment 1;

FIG. 3 is a schematic view illustrating one example of a photomask;

FIG. 4A is a plan view illustrating the manufacturing method of the semiconductor device according to the embodiment 1;

FIG. 4B is a cross-sectional view illustrating the manufacturing method of the semiconductor device according to the embodiment 1;

FIG. 5A is a plan view illustrating the manufacturing method of the semiconductor device according to the embodiment 1;

FIG. 5B is a cross-sectional view illustrating the manufacturing method of the semiconductor device according to the embodiment 1;

FIG. 6A is a plan view illustrating the manufacturing method of the semiconductor device according to the embodiment 1;

FIG. 6B is a cross-sectional view illustrating the manufacturing method of the semiconductor device according to the embodiment 1;

FIG. 7 is a schematic view illustrating one example of a photomask;

FIG. 8A is a plan view illustrating the manufacturing method of the semiconductor device according to the embodiment 1;

FIG. 8B is a cross-sectional view illustrating the manufacturing method of the semiconductor device according to the embodiment 1;

FIG. 9A is a plan view illustrating the manufacturing method of the semiconductor device according to the embodiment 1;

FIG. 9B is a cross-sectional view illustrating the manufacturing method of the semiconductor device according to the embodiment 1;

FIG. 10A is a plan view illustrating the manufacturing method of the semiconductor device according to the embodiment 1;

FIG. 10B is a cross-sectional view illustrating the manufacturing method of the semiconductor device according to the embodiment 1;

FIG. 11 is a schematic view illustrating one example of a photomask;

FIG. 12A is a plan view illustrating the manufacturing method of the semiconductor device according to the embodiment 1;

FIG. 12B is a cross-sectional view illustrating the manufacturing method of the semiconductor device according to the embodiment 1;

FIG. 13A is a plan view illustrating the manufacturing method of the semiconductor device according to the embodiment 1;

FIG. 13B is a cross-sectional view illustrating the manufacturing method of the semiconductor device according to the embodiment 1;

FIG. 14A is a plan view illustrating the manufacturing method of the semiconductor device according to the embodiment 1;

FIG. 14B is a cross-sectional view illustrating the manufacturing method of the semiconductor device according to the embodiment 1;

FIG. 15 is a schematic view illustrating one example of a photomask;

FIG. 16A is a plan view illustrating the manufacturing method of the semiconductor device according to the embodiment 1;

FIG. 16B is a cross-sectional view illustrating the manufacturing method of the semiconductor device according to the embodiment 1;

FIG. 17A is a plan view illustrating the manufacturing method of the semiconductor device according to the embodiment 1;

FIG. 17B is a cross-sectional view illustrating the manufacturing method of the semiconductor device according to the embodiment 1;

FIG. 18A is a plan view illustrating the manufacturing method of the semiconductor device according to the embodiment 1;

FIG. 18B is a cross-sectional view illustrating the manufacturing method of the semiconductor device according to the embodiment 1;

FIG. 19A is a plan view illustrating the manufacturing method of the semiconductor device according to the embodiment 1;

FIG. 19B is a cross-sectional view illustrating the manufacturing method of the semiconductor device according to the embodiment 1;

FIG. 20A is a plan view illustrating the manufacturing method of the semiconductor device according to the embodiment 1;

FIG. 20B is a cross-sectional view illustrating the manufacturing method of the semiconductor device according to the embodiment 1;

FIG. 21A is a plan view illustrating the manufacturing method of the semiconductor device according to the embodiment 1;

FIG. 21B is a cross-sectional view illustrating the manufacturing method of the semiconductor device according to the embodiment 1;

FIG. 22A is a plan view illustrating the manufacturing method of the semiconductor device according to the embodiment 1;

FIG. 22B is a cross-sectional view illustrating the manufacturing method of the semiconductor device according to the embodiment 1;

FIG. 23A is a plan view illustrating the manufacturing method of the semiconductor device according to the embodiment 1;

FIG. 23B is a cross-sectional view illustrating the manufacturing method of the semiconductor device according to the embodiment 1;

FIG. 24A is a plan view illustrating the manufacturing method of the semiconductor device according to the embodiment 1;

FIG. 24B is a cross-sectional view illustrating the manufacturing method of the semiconductor device according to the embodiment 1;

FIG. 25A is a plan view illustrating the manufacturing method of the semiconductor device according to the embodiment 1;

FIG. 25B is a cross-sectional view illustrating the manufacturing method of the semiconductor device according to the embodiment 1;

FIG. 26A is a plan view illustrating the manufacturing method of the semiconductor device according to the embodiment 1;

FIG. 26B is a cross-sectional view illustrating the manufacturing method of the semiconductor device according to the embodiment 1;

FIG. 27A is a plan view illustrating the manufacturing method of the semiconductor device according to the embodiment 1;

FIG. 27B is a cross-sectional view illustrating the manufacturing method of the semiconductor device according to the embodiment 1;

FIG. 28A is a plan view illustrating the manufacturing method of the semiconductor device according to the embodiment 1;

FIG. 28B is a cross-sectional view illustrating the manufacturing method of the semiconductor device according to the embodiment 1;

FIG. 29A is a plan view illustrating the manufacturing method of the semiconductor device according to the embodiment 1;

FIG. 29B is a cross-sectional view illustrating the manufacturing method of the semiconductor device according to the embodiment 1;

FIG. 30A is a plan view illustrating the manufacturing method of the semiconductor device according to the embodiment 1;

FIG. 30B is a cross-sectional view illustrating the manufacturing method of the semiconductor device according to the embodiment 1;

FIG. 31A is a plan view illustrating the manufacturing method of the semiconductor device according to the embodiment 1;

FIG. 31B is a cross-sectional view illustrating the manufacturing method of the semiconductor device according to the embodiment 1;

FIG. 32 is a schematic view illustrating a position where each resist pattern 11 is formed and a position where each resist pattern 15 is formed;

FIG. 33A is a plan view illustrating the manufacturing method of the semiconductor device according to the embodiment 1;

FIG. 33B is a cross-sectional view illustrating the manufacturing method of the semiconductor device according to the embodiment 1;

FIG. 34A is a plan view illustrating the manufacturing method of the semiconductor device according to the embodiment 1;

FIG. 34B is a cross-sectional view illustrating the manufacturing method of the semiconductor device according to the embodiment 1;

FIG. 35A is a plan view illustrating the manufacturing method of the semiconductor device according to the embodiment 1;

FIG. 35B is a cross-sectional view illustrating the manufacturing method of the semiconductor device according to the embodiment 1;

FIG. 36 is a schematic view illustrating one example of a photomask;

FIG. 37A is a plan view illustrating the manufacturing method of the semiconductor device according to the embodiment 1;

FIG. 37B is a cross-sectional view illustrating the manufacturing method of the semiconductor device according to the embodiment 1;

FIG. 38A is a plan view illustrating the manufacturing method of the semiconductor device according to the embodiment 1;

FIG. 38B is a cross-sectional view illustrating the manufacturing method of the semiconductor device according to the embodiment 1;

FIG. 39A is a plan view illustrating the manufacturing method of the semiconductor device according to the embodiment 1;

FIG. 39B is a cross-sectional view illustrating the manufacturing method of the semiconductor device according to the embodiment 1;

FIG. 40 is a schematic view illustrating one example of a photomask;

FIG. 41A is a plan view illustrating the manufacturing method of the semiconductor device according to the embodiment 1;

FIG. 41B is a cross-sectional view illustrating the manufacturing method of the semiconductor device according to the embodiment 1;

FIG. 42A is a plan view illustrating the manufacturing method of the semiconductor device according to the embodiment 1;

FIG. 42B is a cross-sectional view illustrating the manufacturing method of the semiconductor device according to the embodiment 1;

FIG. 43A is a plan view illustrating the manufacturing method of the semiconductor device according to the embodiment 1;

FIG. 43B is a cross-sectional view illustrating the manufacturing method of the semiconductor device according to the embodiment 1;

FIG. 44A is a plan view illustrating the manufacturing method of the semiconductor device according to the embodiment 1;

FIG. 44B is a cross-sectional view illustrating the manufacturing method of the semiconductor device according to the embodiment 1;

FIG. 45A is a plan view illustrating the manufacturing method of the semiconductor device according to the embodiment 1;

FIG. 45B is a cross-sectional view illustrating the manufacturing method of the semiconductor device according to the embodiment 1;

FIG. 46A is a plan view illustrating the manufacturing method of the semiconductor device according to the embodiment 1;

FIG. 46B is a cross-sectional view illustrating the manufacturing method of the semiconductor device according to the embodiment 1;

FIG. 47A is a plan view illustrating the manufacturing method of the semiconductor device according to the embodiment 1;

FIG. 47B is a cross-sectional view illustrating the manufacturing method of the semiconductor device according to the embodiment 1;

FIG. 48A is a plan view illustrating the manufacturing method of the semiconductor device according to the embodiment 1;

FIG. 48B is a cross-sectional view illustrating the manufacturing method of the semiconductor device according to the embodiment 1;

FIG. 49A is a plan view illustrating the manufacturing method of the semiconductor device according to the embodiment 1;

FIG. 49B is a cross-sectional view illustrating the manufacturing method of the semiconductor device according to the embodiment 1;

FIG. 50A is a plan view illustrating the manufacturing method of the semiconductor device according to the embodiment 1;

FIG. 50B is a cross-sectional view illustrating the manufacturing method of the semiconductor device according to the embodiment 1;

FIG. 51A is a plan view illustrating the manufacturing method of the semiconductor device according to the embodiment 1;

FIG. 51B is a cross-sectional view illustrating the manufacturing method of the semiconductor device according to the embodiment 1;

FIG. 52A is a plan view illustrating the manufacturing method of the semiconductor device according to the embodiment 1;

FIG. 52B is a cross-sectional view illustrating the manufacturing method of the semiconductor device according to the embodiment 1;

FIG. 53A is a plan view illustrating the manufacturing method of the semiconductor device according to the embodiment 1;

FIG. 53B is a cross-sectional view illustrating the manufacturing method of the semiconductor device according to the embodiment 1;

FIG. 54A is a plan view illustrating the manufacturing method of the semiconductor device according to the embodiment 1;

FIG. 54B is a cross-sectional view illustrating the manufacturing method of the semiconductor device according to the embodiment 1;

FIG. 55A is a plan view illustrating the manufacturing method of the semiconductor device according to the embodiment 1;

FIG. 55B is a cross-sectional view illustrating the manufacturing method of the semiconductor device according to the embodiment 1;

FIG. 56A is a plan view illustrating the manufacturing method of the semiconductor device according to the embodiment 1;

FIG. 56B is a cross-sectional view illustrating the manufacturing method of the semiconductor device according to the embodiment 1;

FIG. 57A is a plan view illustrating a manufacturing method of a semiconductor device according to an embodiment 2;

FIG. 57B is a cross-sectional view illustrating the manufacturing method of the semiconductor device according to the embodiment 2;

FIG. 58A is a plan view illustrating the manufacturing method of the semiconductor device according to the embodiment 2;

FIG. 58B is a cross-sectional view illustrating the manufacturing method of the semiconductor device according to the embodiment 2;

FIG. 59A is a plan view illustrating the manufacturing method of the semiconductor device according to the embodiment 2;

FIG. 59B is a cross-sectional view illustrating the manufacturing method of the semiconductor device according to the embodiment 2;

FIG. 60A is a plan view illustrating the manufacturing method of the semiconductor device according to the embodiment 2;

FIG. 60B is a cross-sectional view illustrating the manufacturing method of the semiconductor device according to the embodiment 2;

FIG. 61A is a plan view illustrating the manufacturing method of the semiconductor device according to the embodiment 2;

FIG. 61B is a cross-sectional view illustrating the manufacturing method of the semiconductor device according to the embodiment 2;

FIG. 62A is a plan view illustrating the manufacturing method of the semiconductor device according to the embodiment 2;

FIG. 62B is a cross-sectional view illustrating the manufacturing method of the semiconductor device according to the embodiment 2;

FIG. 63A is a plan view illustrating a manufacturing method of a semiconductor device according to Modified Example 1;

FIG. 63B is a cross-sectional view illustrating the manufacturing method of the semiconductor device according to Modified Example 1;

FIG. 64 is a schematic view illustrating one example of a photomask;

FIG. 65A is a plan view illustrating the manufacturing method of the semiconductor device according to Modified Example 1;

FIG. 65B is a cross-sectional view illustrating the manufacturing method of the semiconductor device according to Modified Example 1;

FIG. 66A is a plan view illustrating the manufacturing method of the semiconductor device according to Modified Example 1; and

FIG. 66B is a cross-sectional view illustrating the manufacturing method of the semiconductor device according to Modified Example 1.

### DESCRIPTION OF EMBODIMENTS

A mask pattern is desired to be highly accurate in any places over the entire area of a photomask. In addition, distances among mask patterns of a photomask are desired to correspond to one another. The distance between mask patterns differs, however, in distant places on the photomask due to the effects of distortion or surface roughness in the photomask. That is, a gap arises in the distance between mask patterns of the photomask. If any error is present in the distance between mask patterns of a first photomask, mask patterns of a second photomask are fabricated in consideration of the error in the distance between mask patterns of the first photomask. An error also arises in the distance between mask patterns of the second photomask, however, due to the effects of distortion or surface roughness in the photomask. In addition, the first and second photomasks do not correspond to each other in the distance error between mask patterns of the photomask. It is therefore not easy to fabricate the mask patterns of the second photomask in consideration of the distance error between mask patterns of the first photomask.

Hereinafter, a semiconductor device and a manufacturing method of the semiconductor device according to each embodiment will be described with reference to the accompanying drawings. The configurations of embodiments 1 and 2 to be described hereinafter are merely illustrative, and therefore, the semiconductor device and the manufacturing method of the semiconductor device according to embodiments are not limited to the configurations of the embodiments 1 and 2.

### Embodiment 1

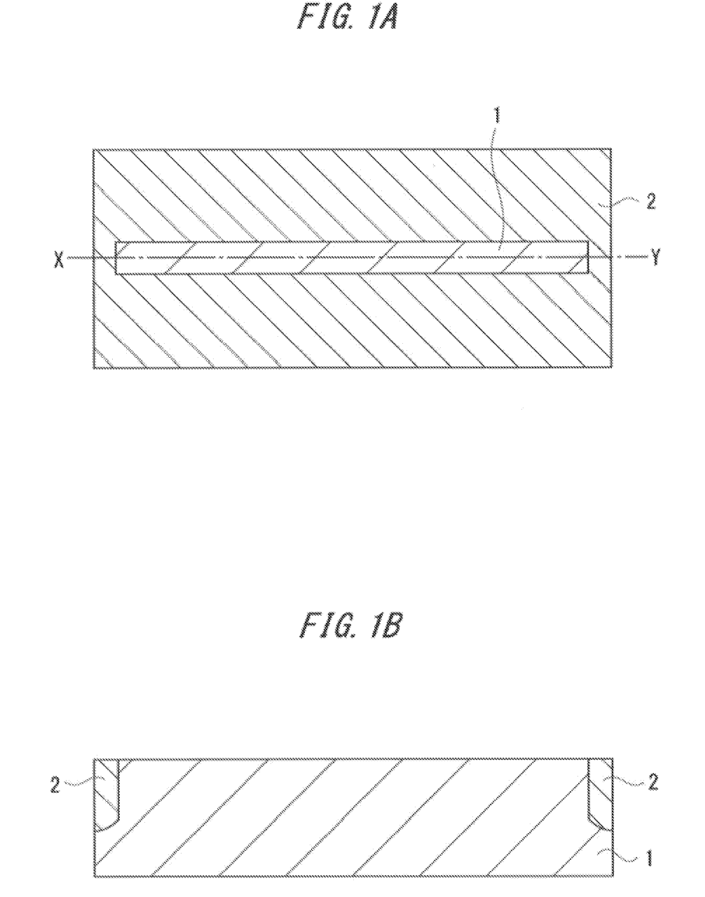

The semiconductor device and the manufacturing method of the semiconductor device according to the embodiment 1 will be described with reference to FIGS. 1A to 56B. The embodiment 1 will be described by citing, as an example, a semiconductor device provided with a MOS (Metal Oxide Semiconductor) transistor which is one example of a semiconductor element.

FIG. 1A is a plan view illustrating the manufacturing method of the semiconductor device according to the embodiment 1. FIG. 1B is a cross-sectional view illustrating the manufacturing method of the semiconductor device according to the embodiment 1, and represents a cross section along the single-dot chain line X-Y of FIG. 1A. In steps illustrated in FIGS. 1A and 1B, an element-isolating insulating film 2 of a semiconductor substrate 1 is formed by, for example, an STI (Shallow Trench Isolation) method. The semiconductor substrate 1 is, for example, a silicon (Si) substrate. The semiconductor substrate 1 is one example of a substrate. The element-isolating insulating film 2 is, for example, a silicon dioxide film (SiO₂).

The element-isolating insulating film 2 may be formed by, for example, the method described below. First, a resist is formed (coated) on the semiconductor substrate 1. Mask patterns of a photomask for element isolation are exposure-transferred (transferred) to the resist using an exposure apparatus. The resist to which the mask patterns of the photomask for element isolation are transferred is developed to form resist patterns on the semiconductor substrate 1. Anisotropic dry etching is performed with the resist patterns on the semiconductor substrate 1 as a mask to form trenches in the semiconductor substrate 1. A silicon dioxide film is formed on the entire surface of the semiconductor substrate 1 by, for example, a CVD (Chemical Vapor Deposition) method using TEOS (tetra ethoxy silane) as a raw material. The silicon dioxide film formed on the entire surface of the semiconductor substrate 1 is planarized by CMP (Chemical Mechanical Polishing) to form the element-isolating insulating film 2 on the semiconductor substrate 1. An active region (element-forming region) is defined in the semiconductor substrate 1 as the result of the element-isolating insulating film 2 being formed on the semiconductor substrate 1. FIG. 1B illustrates an example in which the front surface of the semiconductor substrate 1 is level with the element-isolating insulating film 2. Without limitation to this example, the front surface of the semiconductor substrate 1 may be higher than the element-isolating insulating film 2. Alternatively, the front surface of the semiconductor substrate 1 may be lower than the element-isolating insulating film 2.

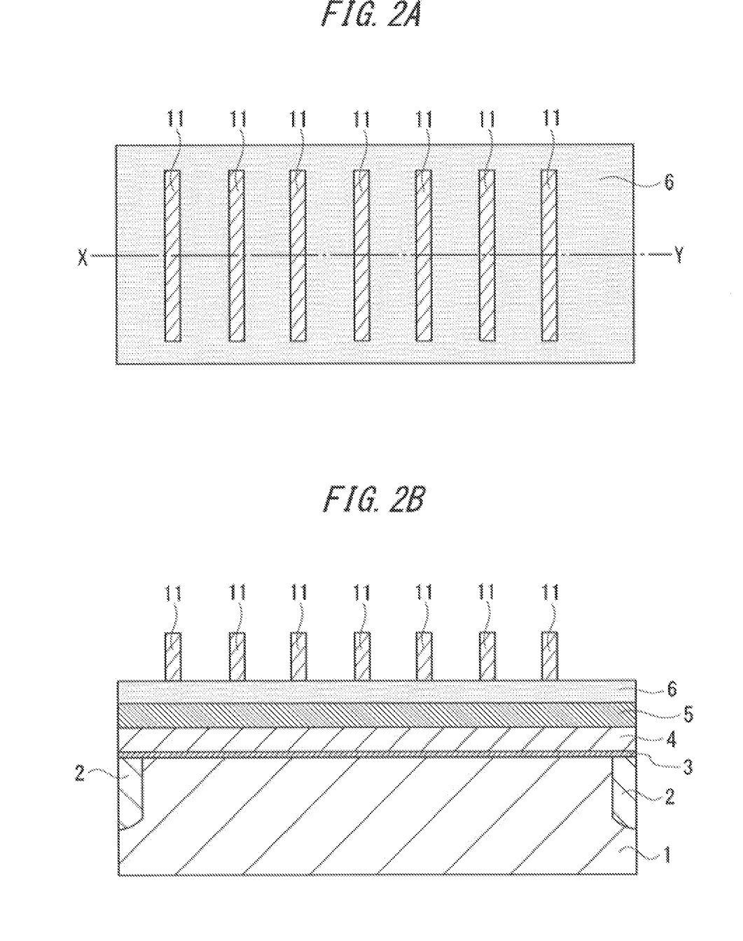

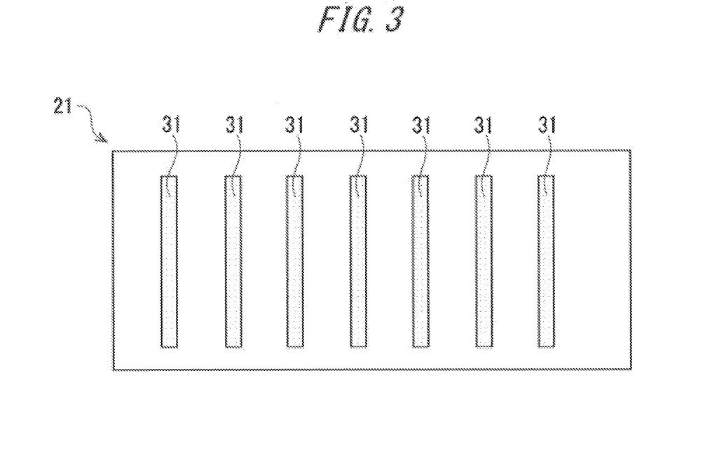

FIG. 2A is a plan view illustrating the manufacturing method of the semiconductor device according to the embodiment 1. FIG. 2B is a cross-sectional view illustrating the manufacturing method of the semiconductor device according to the embodiment 1, and represents a cross section along the single-dot chain line X-Y of FIG. 2A. In steps illustrated in FIGS. 2A and 2B, a silicon dioxide film (SiO₂) 3, a dummy gate 4, a hard mask 5 and a hard mask 6 are formed in order on the semiconductor substrate 1. The dummy gate 4 is, for example, an amorphous silicon film (α-Si). The hard mask 5 is, for example, a silicon dioxide film (SiO₂). The hard mask 6 is, for example, a silicon nitride film (SiN). The thickness of the silicon dioxide film 3 is, for example, approximately 2 nm. The film thickness of the dummy gate 4 is, for example, approximately 50 nm. The film thickness of the hard mask 5 is, for example, approximately 50 nm. The film thickness of the hard mask 6 is, for example, approximately 50 nm. The silicon dioxide film 3, the dummy gate 4 and the hard masks 5 and 6 are formed by, for example, a CVD (Chemical Vapor Deposition) method. In the steps illustrated in FIGS. 2A and 2B, a resist is formed (coated) on the hard mask 6 above the semiconductor substrate 1, and then mask patterns 31 formed in a photomask 21 illustrated in FIG. 3 are exposure-transferred to the resist using an exposure apparatus. The photomask 21 is placed in a first position above the semiconductor substrate 1. Note that an antireflection film may be formed between the resist and the hard mask 6. In the steps illustrated in FIGS. 2A and 2B, the resist to which the mask patterns 31 of the photomask 21 illustrated in FIG. 3 are transferred is developed to form one or more first resist patterns on the hard mask 6 above the semiconductor substrate 1. The first resist patterns include a plurality of resist patterns 11. Each resist pattern 11 is one example of a first pattern. The plurality of resist patterns 11 is formed on the hard mask 6, so as to align in the plane direction of the semiconductor substrate 1. The plurality of resist patterns 11 is formed on the hard mask 6, so that the lengthwise direction of each resist pattern 11 and the lengthwise direction of the active region of the semiconductor substrate 1 are orthogonal to each other.

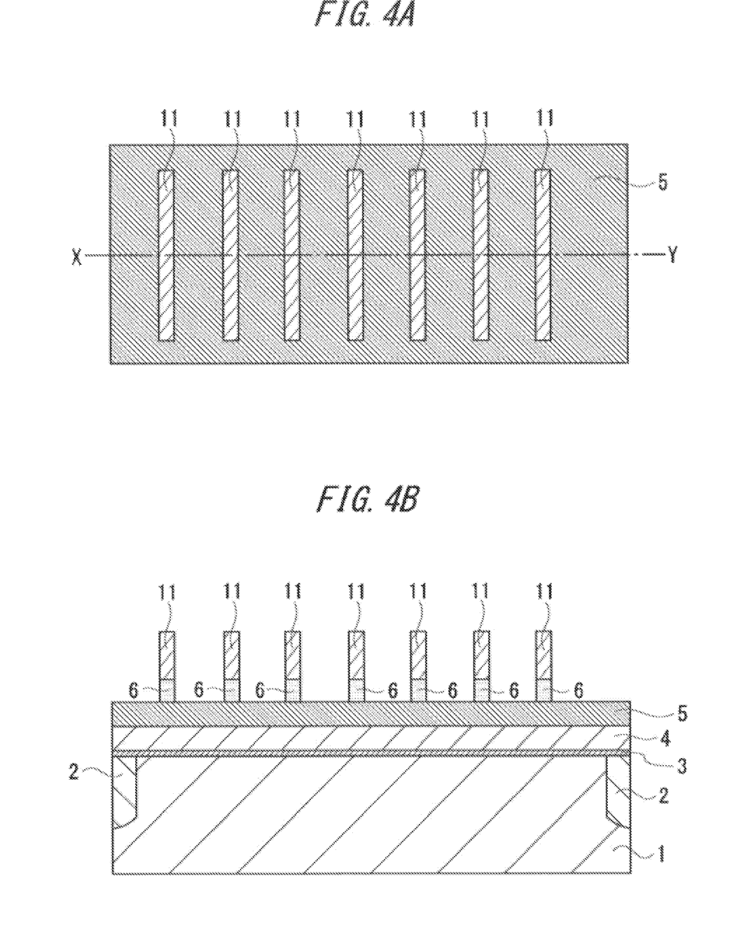

FIG. 4A is a plan view illustrating the manufacturing method of the semiconductor device according to the embodiment 1. FIG. 4B is a cross-sectional view illustrating the manufacturing method of the semiconductor device according to the embodiment 1, and represents a cross section along the single-dot chain line X-Y of FIG. 4A. In steps illustrated in FIGS. 4A and 4B, anisotropic dry etching is performed with the resist patterns 11 as a mask to partially remove and process the hard mask 6. That is, the pattern shape of each resist pattern 11 is transferred to the hard mask 6 to form a plurality of hard masks 6 on the hard mask 5. Accordingly, the plurality of hard masks 6 is formed on the hard mask 5, so that the lengthwise direction of the hard mask 6 and the lengthwise direction of the active region of the semiconductor substrate 1 are orthogonal to each other. Anisotropic dry etching is performed using a gas containing, for example, CF₄, C₄F₈, CH₂F₂, CHF₃ or CH₃F.

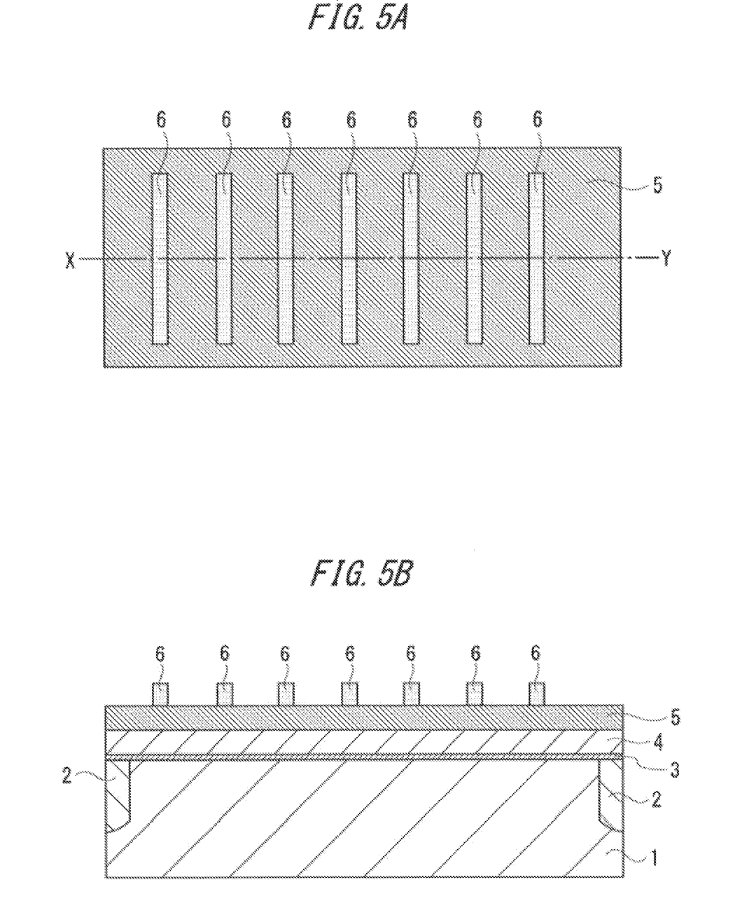

FIG. 5A is a plan view illustrating the manufacturing method of the semiconductor device according to the embodiment 1. FIG. 5B is a cross-sectional view illustrating the manufacturing method of the semiconductor device according to the embodiment 1, and represents a cross section along the single-dot chain line X-Y of FIG. 5A. In steps illustrated in FIGS. 5A and 5B, the resist patterns 11 are removed by, for example, ashing.

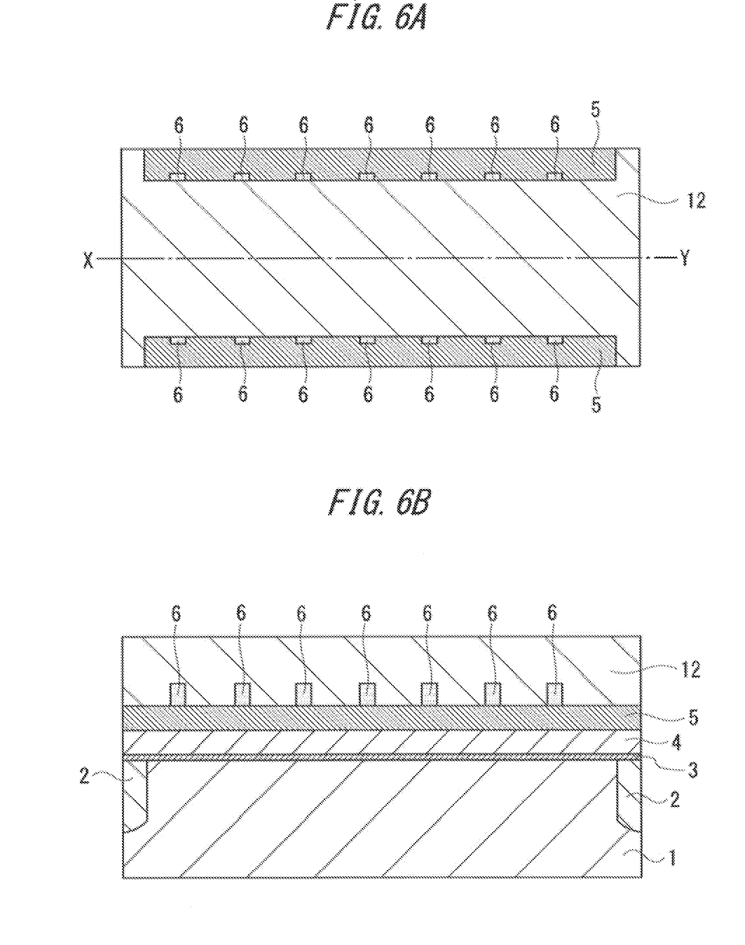

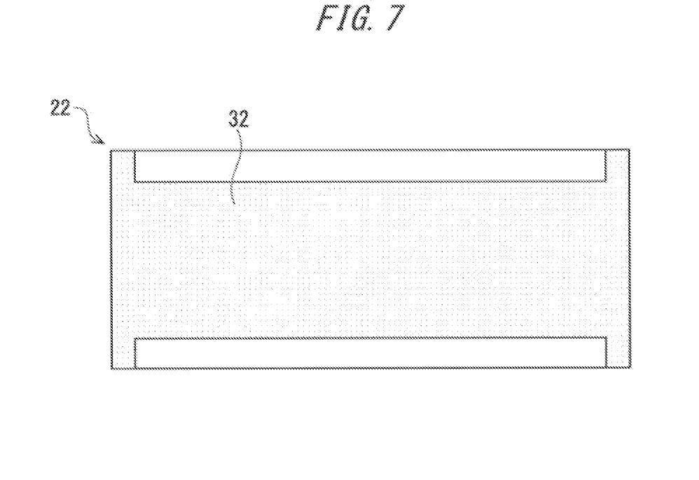

FIG. 6A is a plan view illustrating the manufacturing method of the semiconductor device according to the embodiment 1. FIG. 6B is a cross-sectional view illustrating the manufacturing method of the semiconductor device according to the embodiment 1, and represents a cross section along the single-dot chain line X-Y of FIG. 6A. In steps illustrated in FIGS. 6A and 6B, a resist is formed (coated) on the hard mask 5 above the semiconductor substrate 1, and then a mask pattern 32 formed in a photomask 22 illustrated in FIG. 7 is exposure-transferred to the resist using an exposure apparatus. Note that an antireflection film may be formed between the resist and the hard mask 5. In the steps illustrated in FIGS. 6A and 6B, the resist to which the mask pattern 32 of the photomask 22 is transferred is developed to form a resist pattern 12 on the hard mask 5 above the semiconductor substrate 1.

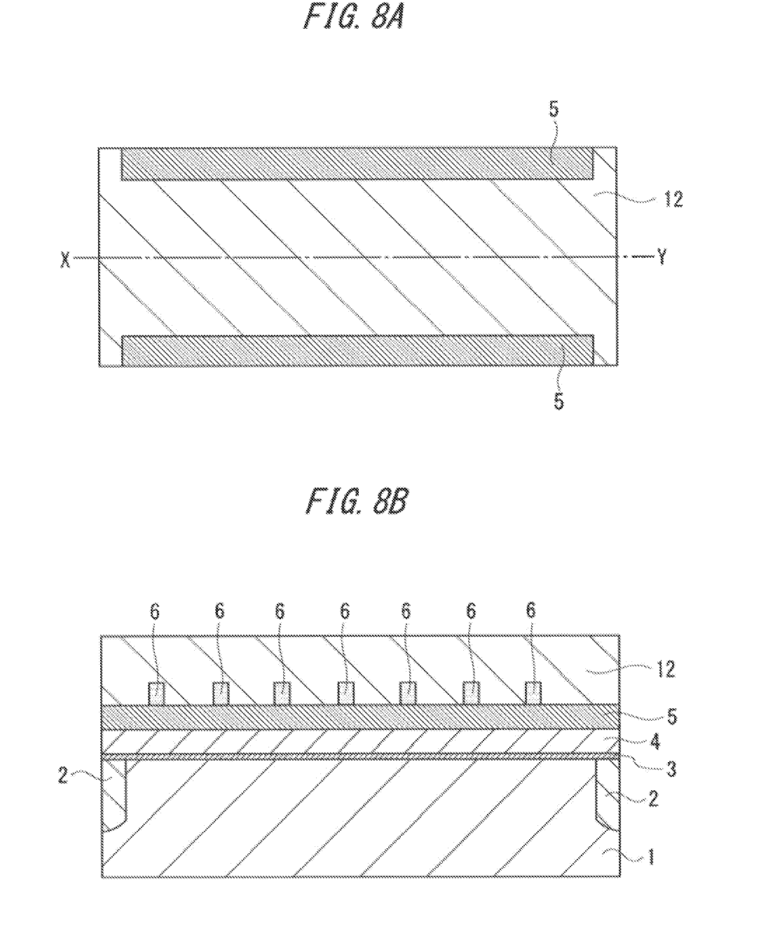

FIG. 8A is a plan view illustrating the manufacturing method of the semiconductor device according to the embodiment 1. FIG. 8B is a cross-sectional view illustrating the manufacturing method of the semiconductor device according to the embodiment 1, and represents a cross section along the single-dot chain line X-Y of FIG. 8A. In steps illustrated in FIGS. 8A and 8B, anisotropic dry etching is performed with the resist pattern 12 as a mask to remove hard masks 6 exposed out of places where the resist pattern 12 is opened. Consequently, both ends of each hard mask 6 are removed, thus reducing the long-side length of each hard mask 6. Anisotropic dry etching is performed using a gas containing, for example, CF₄, C₄F₈, CH₂F₂, CHF₃ or CH₃F.

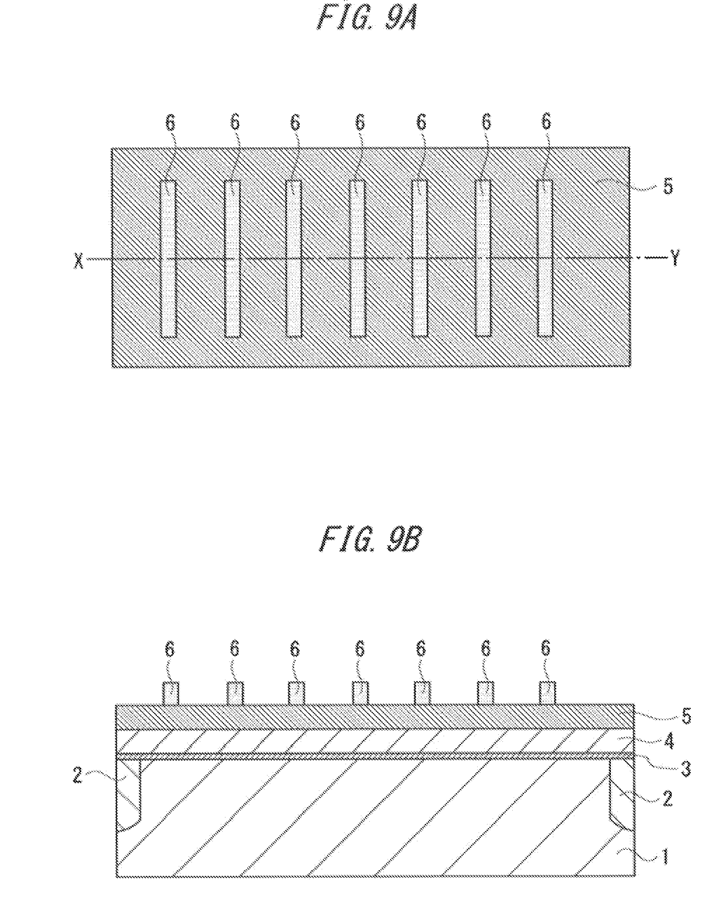

FIG. 9A is a plan view illustrating the manufacturing method of the semiconductor device according to the embodiment 1. FIG. 9B is a cross-sectional view illustrating the manufacturing method of the semiconductor device according to the embodiment 1, and represents a cross section along the single-dot chain line X-Y of FIG. 9A. In steps illustrated in FIGS. 9A and 9B, the resist pattern 12 is removed by, for example, ashing.

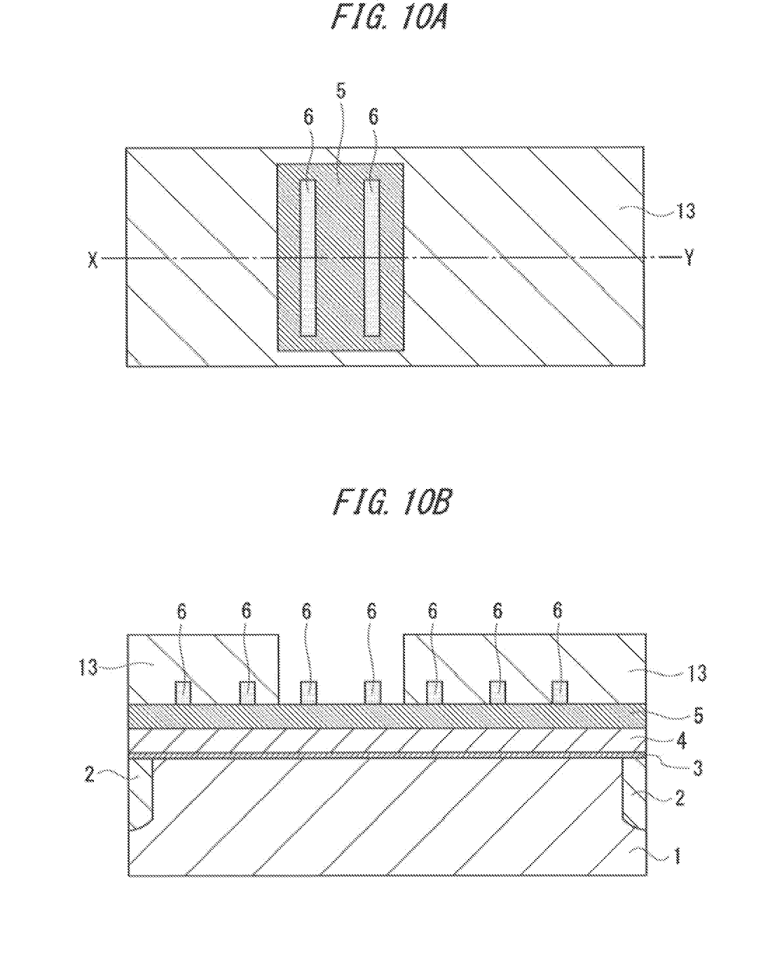

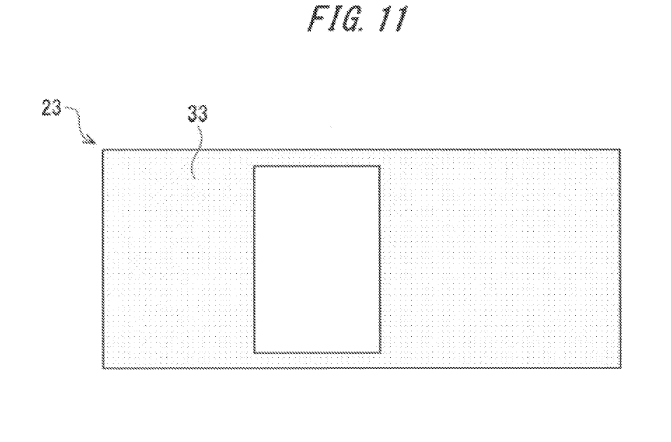

FIG. 10A is a plan view illustrating the manufacturing method of the semiconductor device according to the embodiment 1. FIG. 10B is a cross-sectional view illustrating the manufacturing method of the semiconductor device according to the embodiment 1, and represents a cross section along the single-dot chain line X-Y of FIG. 10A. In steps illustrated in FIGS. 10A and 10B, a resist is formed (coated) on the hard mask 5 above the semiconductor substrate 1, and then a mask pattern 33 formed in a photomask 23 illustrated in FIG. 11 is exposure-transferred to the resist using an exposure apparatus. Note that an antireflection film may be formed between the resist and the hard mask 5. In the steps illustrated in FIGS. 10A and 10B, the resist to which the mask pattern 33 of the photomask 23 is transferred is developed to form a resist pattern 13 on the hard mask 5 above the semiconductor substrate 1.

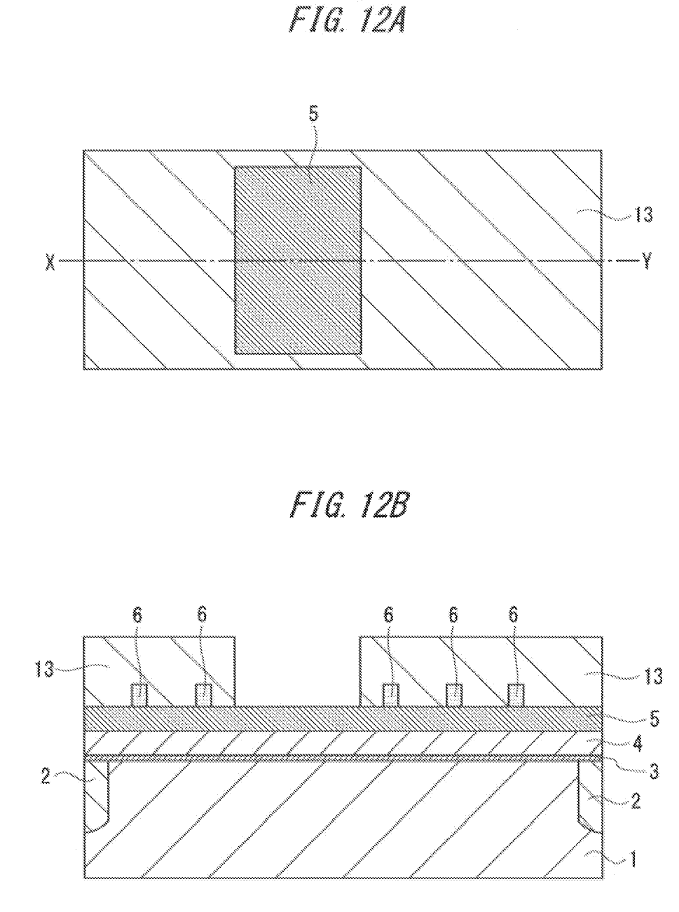

FIG. 12A is a plan view illustrating the manufacturing method of the semiconductor device according to the embodiment 1. FIG. 12B is a cross-sectional view illustrating the manufacturing method of the semiconductor device according to the embodiment 1, and represents a cross section along the single-dot chain line X-Y of FIG. 12A. In steps illustrated in FIGS. 12A and 12B, anisotropic dry etching is performed with the resist pattern 13 as a mask to remove hard masks 6 exposed out of places where the resist pattern 13 is opened. Consequently, at least two adjacent hard masks 6 are removed. Anisotropic dry etching is performed using a gas containing, for example, CF₄, C₄F₈, CH₂F₂, CHF₃ or CH₃F.

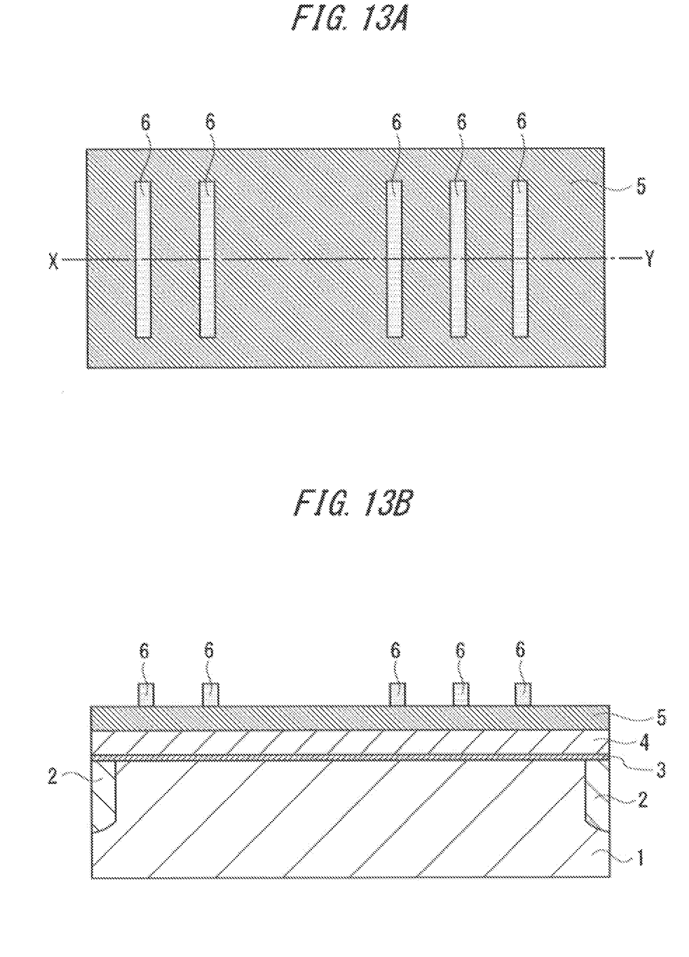

FIG. 13A is a plan view illustrating the manufacturing method of the semiconductor device according to the embodiment 1. FIG. 13B is a cross-sectional view illustrating the manufacturing method of the semiconductor device according to the embodiment 1, and represents a cross section along the single-dot chain line X-Y of FIG. 13A. In steps illustrated in FIGS. 13A and 13B, the resist pattern 13 is removed by, for example, ashing.

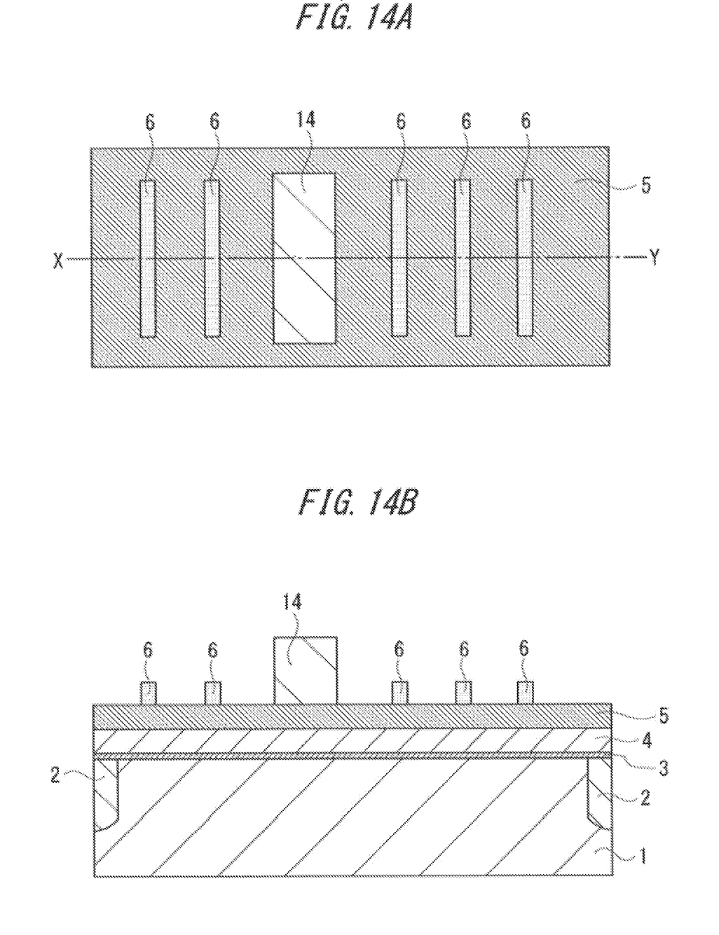

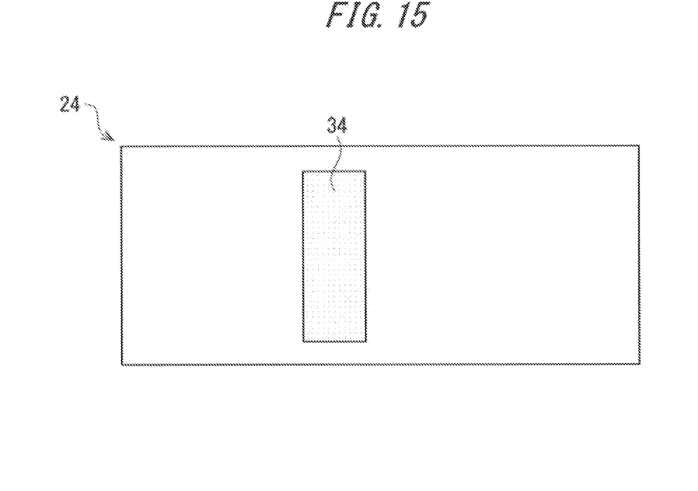

FIG. 14A is a plan view illustrating the manufacturing method of the semiconductor device according to the embodiment 1. FIG. 14B is a cross-sectional view illustrating the manufacturing method of the semiconductor device according to the embodiment 1, and represents a cross section along the single-dot chain line X-Y of FIG. 14A. In steps illustrated in FIGS. 14A and 14B, a resist is formed (coated) on the hard mask 5 above the semiconductor substrate 1, and then a mask pattern 34 formed in a photomask 24 illustrated in FIG. 15 is exposure-transferred to the resist using an exposure apparatus. Note that an antireflection film may be formed between the resist and the hard mask 5. In the steps illustrated in FIGS. 14A and 14B, the resist to which the mask pattern 34 of the photomask 24 is transferred is developed to form a third resist pattern on the hard mask 5 above the semiconductor substrate 1. The third resist pattern includes a resist pattern 14. The resist pattern 14 is one example of a third pattern. The resist pattern 14 covers the places where the hard masks 6 are removed in the steps illustrated in FIGS. 12A and 12B. Accordingly, the resist pattern 14 is formed on the hard mask 5, such that the positions where at least two resist patterns 11, among the plurality of resist patterns 11, are formed and the position where the resist pattern 14 is formed overlap with each other in the vertical direction of the semiconductor substrate 1. The short-side width of the resist pattern 14 is larger than the short-side width of each resist pattern 11. Accordingly, the short-side width of the resist pattern 14 is larger than the short-side width of each hard mask 6. The embodiment 1 represents an example in which the short-side width of the resist pattern 14 is equal to the pitch of the resist patterns 11 which is a sum of the short-side width of each resist pattern 11 and the distance between adjacent resist patterns 11. Without limitation to this example, the short-side width of the resist pattern 14 may be an integer multiple of the pitch of the resist patterns 11.

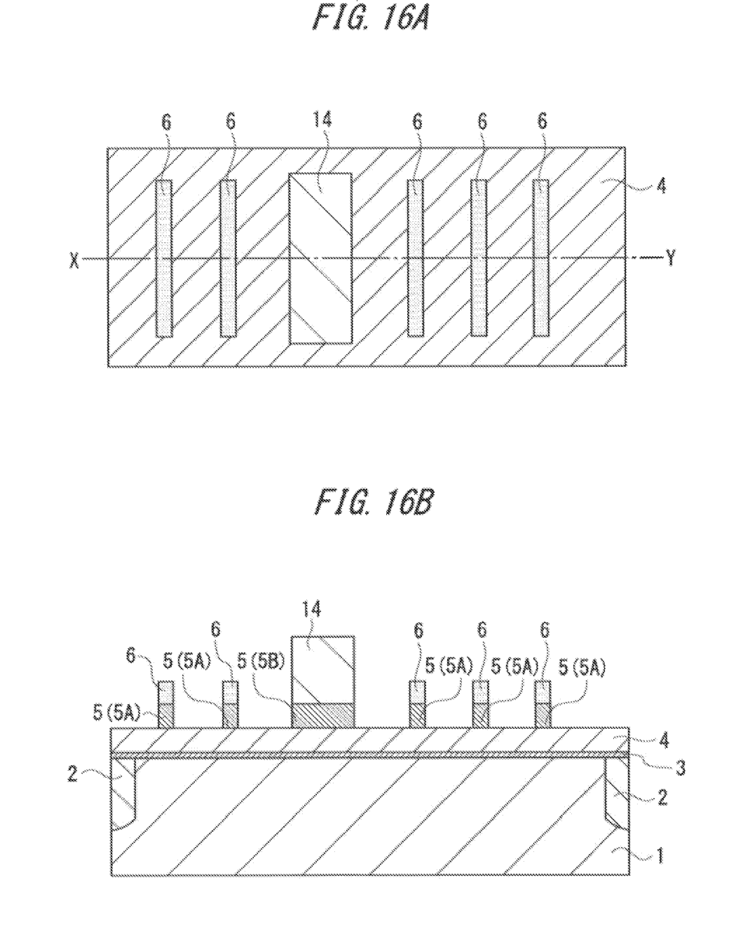

FIG. 16A is a plan view illustrating the manufacturing method of the semiconductor device according to the embodiment 1. FIG. 16B is a cross-sectional view illustrating the manufacturing method of the semiconductor device according to the embodiment 1, and represents a cross section along the single-dot chain line X-Y of FIG. 16A. In steps illustrated in FIGS. 16A and 16B, anisotropic dry etching is performed with the hard masks 6 and the resist pattern 14 as a mask to partially remove and process the hard mask 5. That is, the pattern shapes of the hard masks 6 and the resist pattern 14 are transferred to the hard mask 5 to form a plurality of hard masks 5 on the dummy gate 4. Accordingly, the plurality of hard masks 5 is formed on the dummy gate 4, such that the lengthwise direction of each hard mask 5 and the lengthwise direction of the active region of the semiconductor substrate 1 are orthogonal to each other. The plurality of hard masks 5 includes hard masks 5A smaller in width than a hard mask 5B and the hard mask 5B larger in width than the hard masks 5A. Anisotropic dry etching is performed using a gas containing, for example, CF₄, C₄F₈, CH₂F₂, CHF₃ or CH₃F.

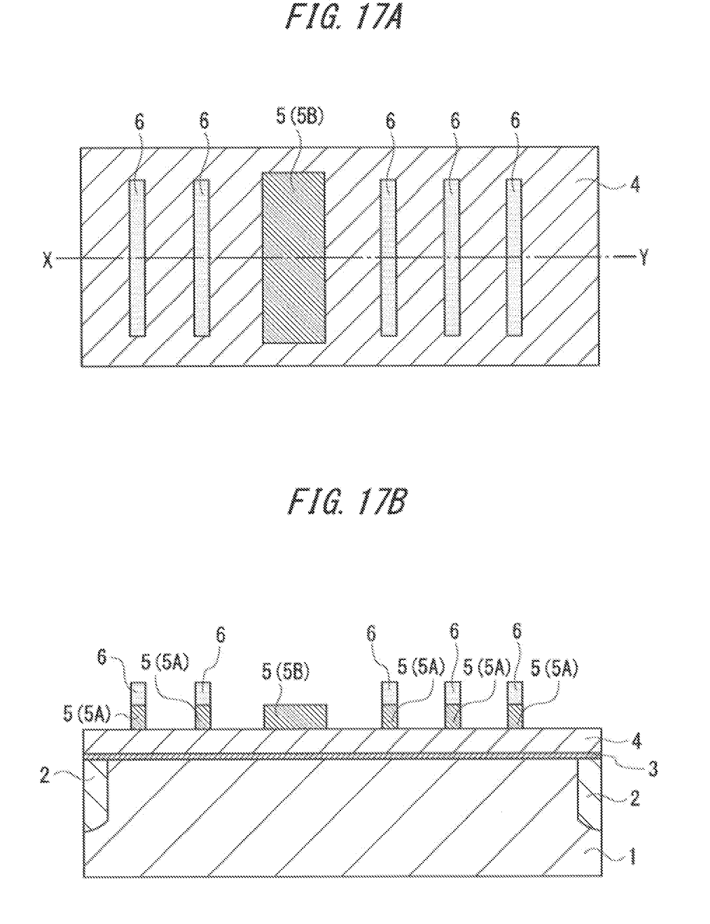

FIG. 17A is a plan view illustrating the manufacturing method of the semiconductor device according to the embodiment 1. FIG. 17B is a cross-sectional view illustrating the manufacturing method of the semiconductor device according to the embodiment 1, and represents a cross section along the single-dot chain line X-Y of FIG. 17A. In steps illustrated in FIGS. 17A and 17B, the resist pattern 14 is removed by, for example, ashing.

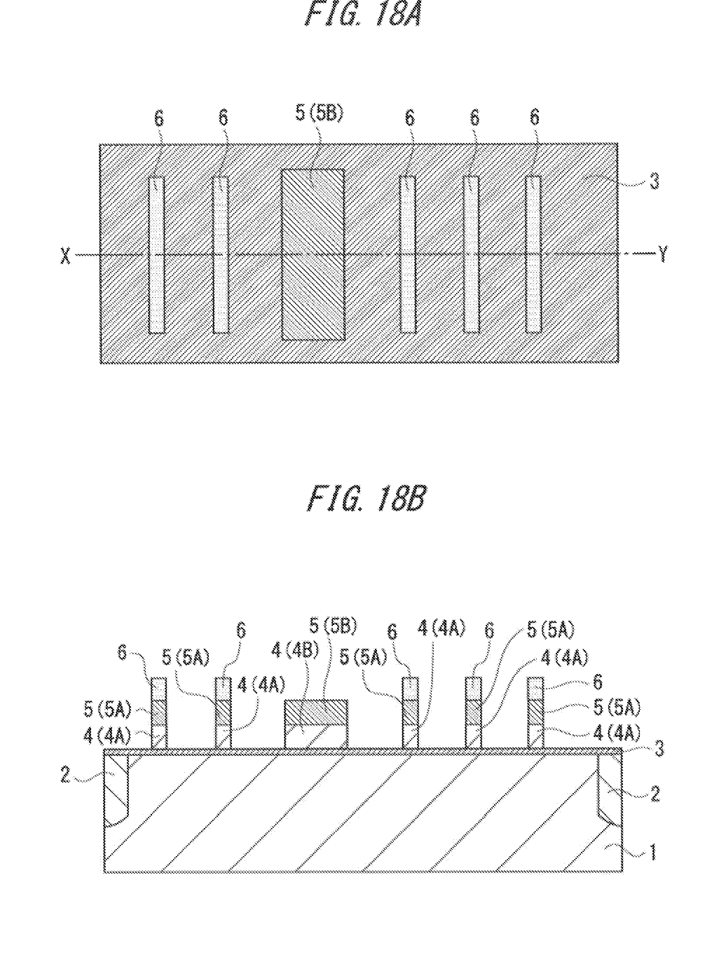

FIG. 18A is a plan view illustrating the manufacturing method of the semiconductor device according to the embodiment 1. FIG. 18B is a cross-sectional view illustrating the manufacturing method of the semiconductor device according to the embodiment 1, and represents a cross section along the single-dot chain line X-Y of FIG. 18A. In steps illustrated in FIGS. 18A and 18B, anisotropic dry etching is performed with the hard masks 5B and 6 as a mask to partially remove and process the dummy gate 4. That is, the pattern shapes of the hard masks 5B and 6 are transferred to the dummy gate 4 to form a plurality of dummy gates 4 on the silicon dioxide film 3. Accordingly, the plurality of dummy gates 4 is formed on the silicon dioxide film 3, such that the lengthwise direction of each dummy gate 4 and the lengthwise direction of the active region of the semiconductor substrate 1 are orthogonal to each other. The plurality of dummy gates 4 includes dummy gates 4A smaller in width than a dummy gate 4B and the dummy gate 4B larger in width than the dummy gates 4A. Anisotropic dry etching is performed using a gas containing, for example, Cl₂, HBr, CF₄ or SF₆.

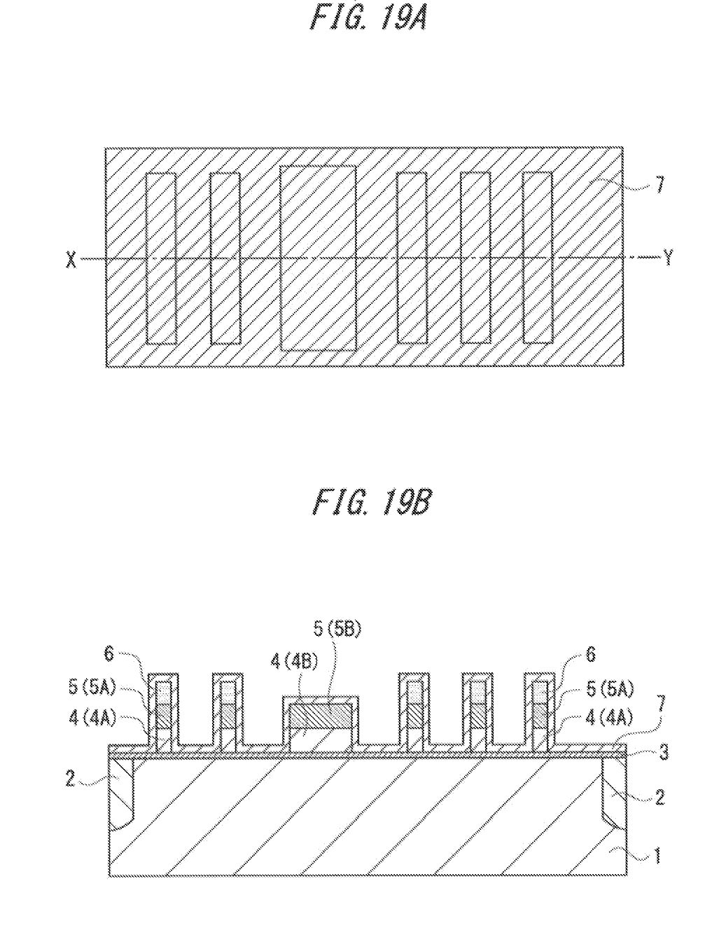

FIG. 19A is a plan view illustrating the manufacturing method of the semiconductor device according to the embodiment 1. FIG. 19B is a cross-sectional view illustrating the manufacturing method of the semiconductor device according to the embodiment 1, and represents a cross section along the single-dot chain line X-Y of FIG. 19A. In steps illustrated in FIGS. 19A and 19B, a spacer insulating film 7 is deposited on the entire surface of the semiconductor substrate 1 by, for example, a CVD method. Consequently, the spacer insulating film 7 is formed so as to cover the dummy gates 4 and the hard masks 5 and 6. The thickness of the spacer insulating film 7 is approximately 10 nm. The spacer insulating film 7 is, for example, a silicon nitride film. The spacer insulating film 7 may be a silicon dioxide film (SiO₂) or a high-dielectric insulating film, such as an HfO₂, HfSiO, HfAlON, Y₂O₃, ZrO, TiO or TaO film.

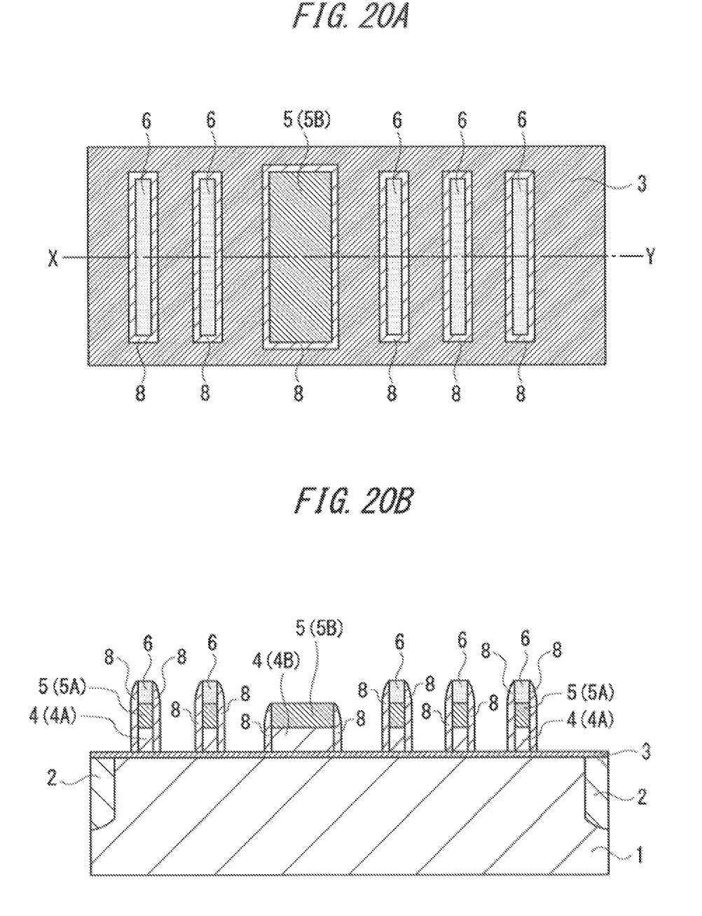

FIG. 20A is a plan view illustrating the manufacturing method of the semiconductor device according to the embodiment 1. FIG. 20B is a cross-sectional view illustrating the manufacturing method of the semiconductor device according to the embodiment 1, and represents a cross section along the single-dot chain line X-Y of FIG. 20A. In steps illustrated in FIGS. 20A and 20B, anisotropic dry etching is performed on the spacer insulating film 7 to form sidewalls 8 on the side surfaces of the dummy gates 4 and the hard masks 5 and 6. Anisotropic dry etching is performed using a gas containing, for example, CF₄, C₄F₈, CH₂F₂, CHF₃ or CH₃F.

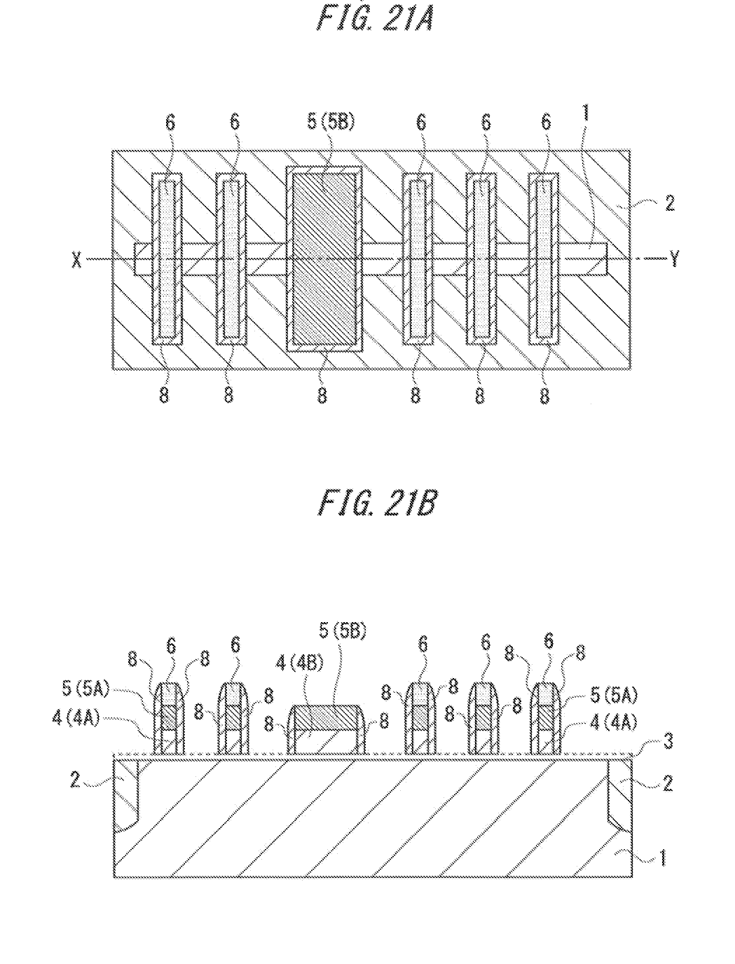

FIG. 21A is a plan view illustrating the manufacturing method of the semiconductor device according to the embodiment 1, where the plan view is taken through the silicon dioxide film 3 illustrated in FIG. 20A. FIG. 21B is a cross-sectional view illustrating the manufacturing method of the semiconductor device according to the embodiment 1, and represents a cross section along the single-dot chain line X-Y of FIG. 21A. FIG. 21B illustrates a cross-sectional view taken through the silicon dioxide film 3 illustrated in FIG. 20B.

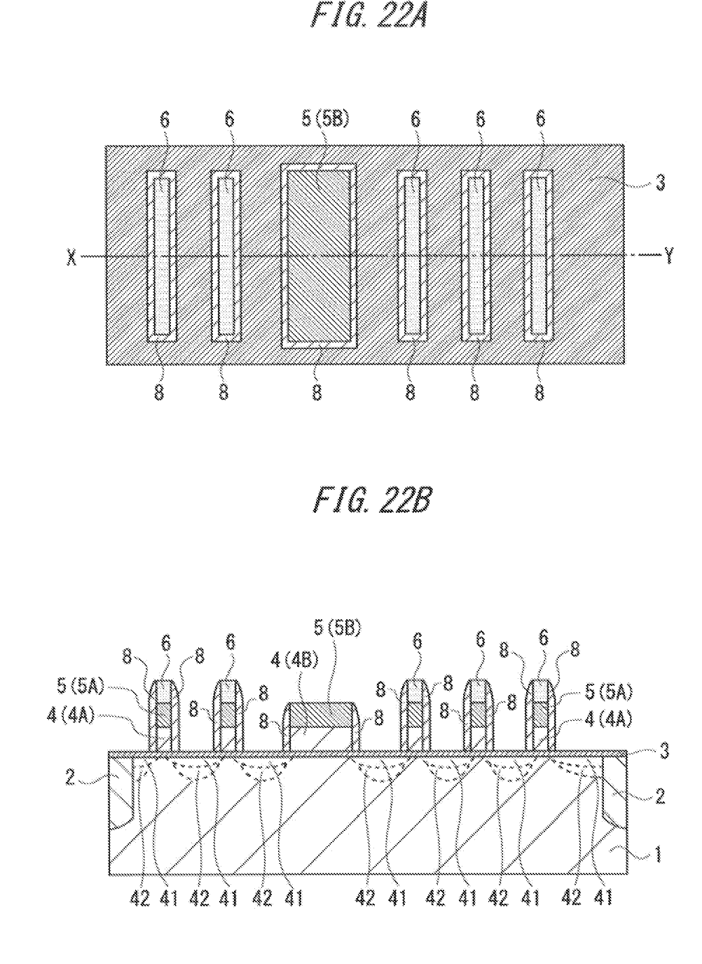

FIG. 22A is a plan view illustrating the manufacturing method of the semiconductor device according to the embodiment 1. FIG. 22B is a cross-sectional view illustrating the manufacturing method of the semiconductor device according to the embodiment 1, and represents a cross section along the single-dot chain line X-Y of FIG. 22A. In steps illustrated in FIGS. 22A and 22B, impurity implantation is performed to form LDD regions 41 and source-drain regions 42 in the active region of the semiconductor substrate 1. In the steps illustrated in FIGS. 22A and 22B, impurity implantation may also be performed to form extension regions, pocket regions and halo regions in the active region of the semiconductor substrate 1. In the steps illustrated in FIGS. 22A and 22B, co-implantation may also be performed to implant carbon (C) or the like into the active region of the semiconductor substrate 1. Note that in FIGS. 22A and 22B, the extension regions, the pocket regions and the halo regions are excluded from the illustration. Also note that in FIGS. 22A and 22B, impurities implanted into the element-isolating insulating film 2, the hard masks 6, the sidewalls 8 and the like are excluded from the illustration. In the steps illustrated in FIGS. 22A and 22B, stress-engineering and resistance-lowering processes, such as etching, deposition and epitaxial growth (Si, SiGe, SiC or the like), may be performed on the source-drain regions 42.

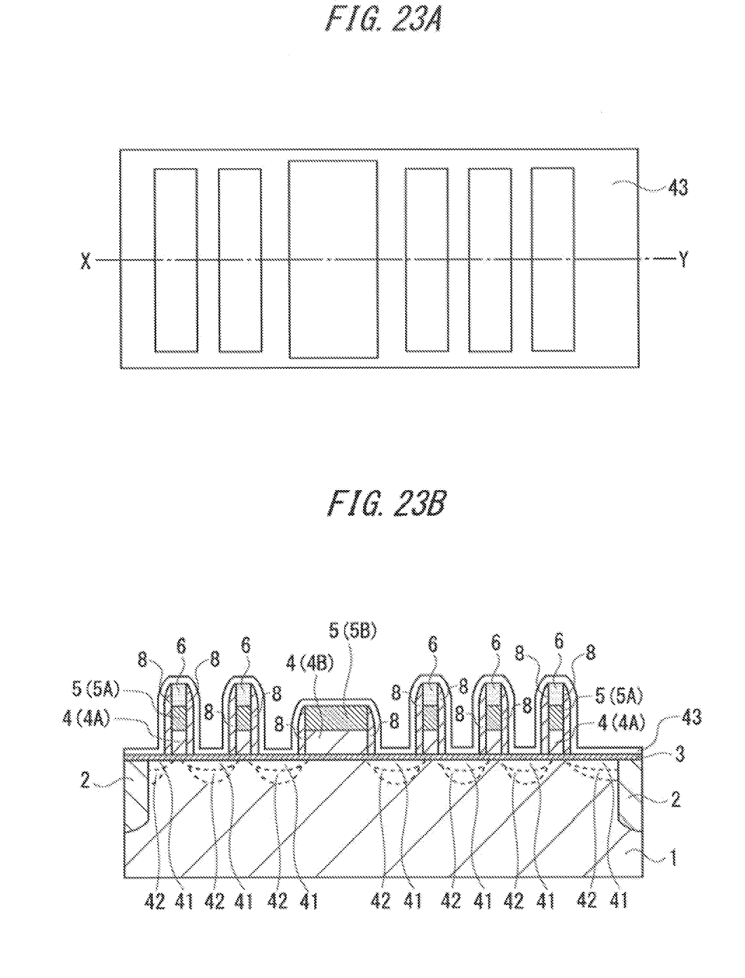

FIG. 23A is a plan view illustrating the manufacturing method of the semiconductor device according to the embodiment 1. FIG. 23B is a cross-sectional view illustrating the manufacturing method of the semiconductor device according to the embodiment 1, and represents a cross section along the single-dot chain line X-Y of FIG. 23A. In steps illustrated in FIGS. 23A and 23B, a contact etch stop layer (CESL, Contact Etch Stop Layer) 43 is formed on the entire surface of the semiconductor substrate 1 by, for example, a CVD method. Consequently, the silicon dioxide film 3, the hard masks 6 and the sidewalls 8 are covered with the contact etch stop layer 43. The contact etch stop layer 43 is, for example, a silicon nitride film. The film thickness of the contact etch stop layer 43 is, for example, approximately 10 nm. The contact etch stop layer 43 may be a silicon dioxide film or a high-dielectric insulating film, such as an HfO₂, HfSiO, HfAlON, Y₂O₃, ZrO, TiO or TaO film.

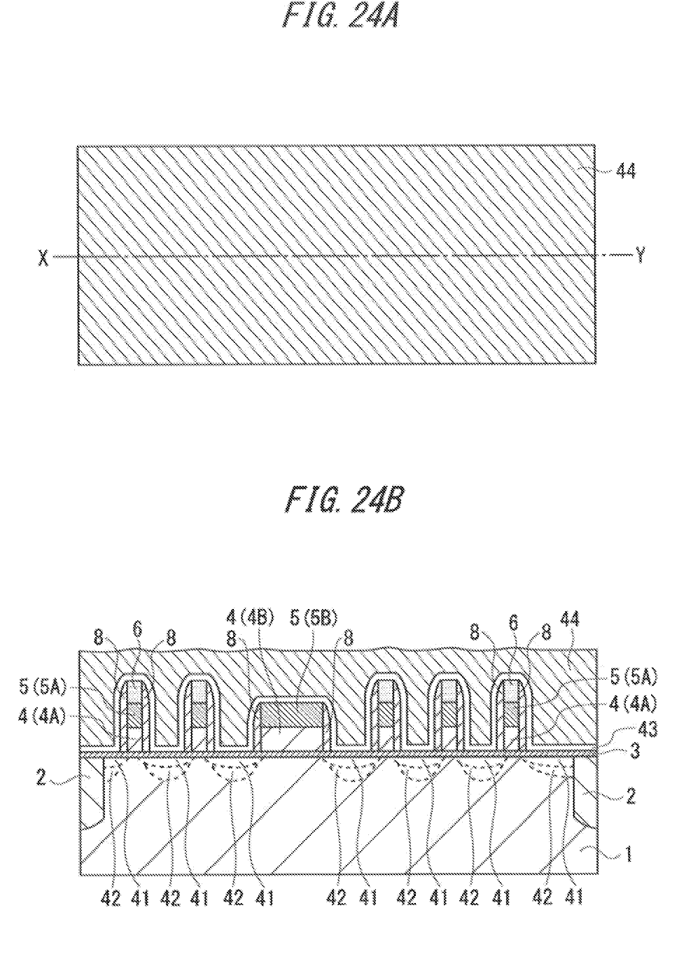

FIG. 24A is a plan view illustrating the manufacturing method of the semiconductor device according to the embodiment 1. FIG. 24B is a cross-sectional view illustrating the manufacturing method of the semiconductor device according to the embodiment 1, and represents a cross section along the single-dot chain line X-Y of FIG. 24A. In steps illustrated in FIGS. 24A and 24B, an interlayer insulating film 44 is formed on the entire surface of the semiconductor substrate 1 by, for example, a CVD method. Consequently, the interlayer insulating film 44 is formed so as to cover the contact etch stop layer 43. The interlayer insulating film 44 is, for example, a silicon dioxide film. Alternatively, the interlayer insulating film 44 may be formed using, for example, TEOS, USG (Undoped Silicate Glass), BPSG (Boron Phosphorus Silicate Glass), SiOC, or a porous low-k material.

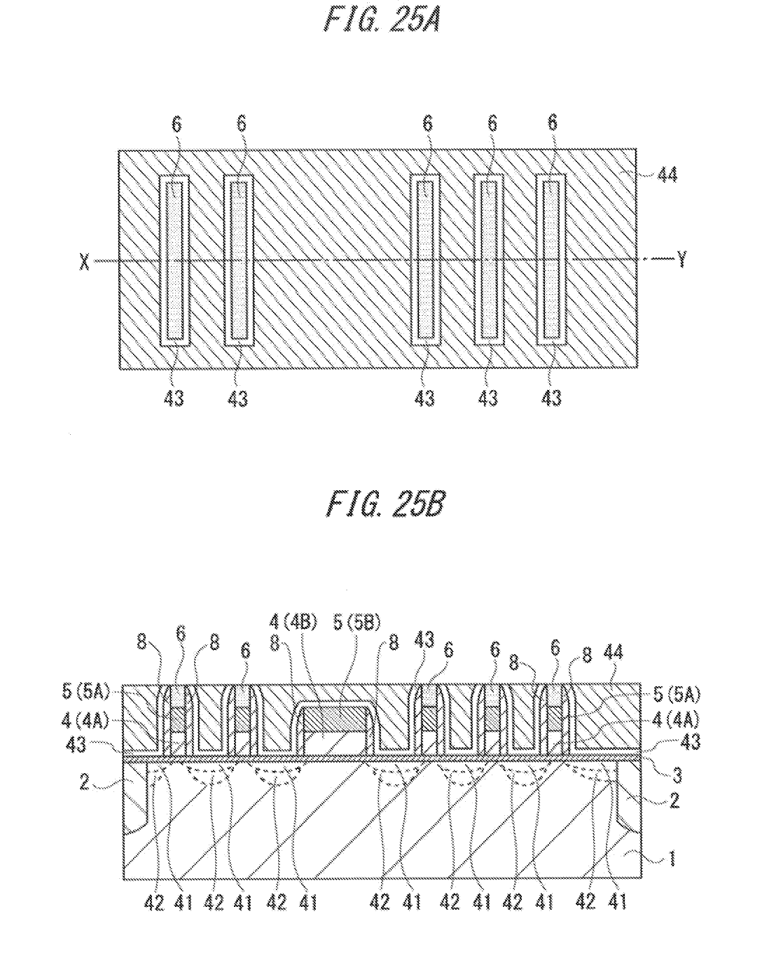

FIG. 25A is a plan view illustrating the manufacturing method of the semiconductor device according to the embodiment 1. FIG. 25B is a cross-sectional view illustrating the manufacturing method of the semiconductor device according to the embodiment 1, and represents a cross section along the single-dot chain line X-Y of FIG. 25A. In steps illustrated in FIGS. 25A and 25B, the interlayer insulating film 44 is planarized by CMP to expose the hard masks 6 and the contact etch stop layer 43 out of the interlayer insulating film 44.

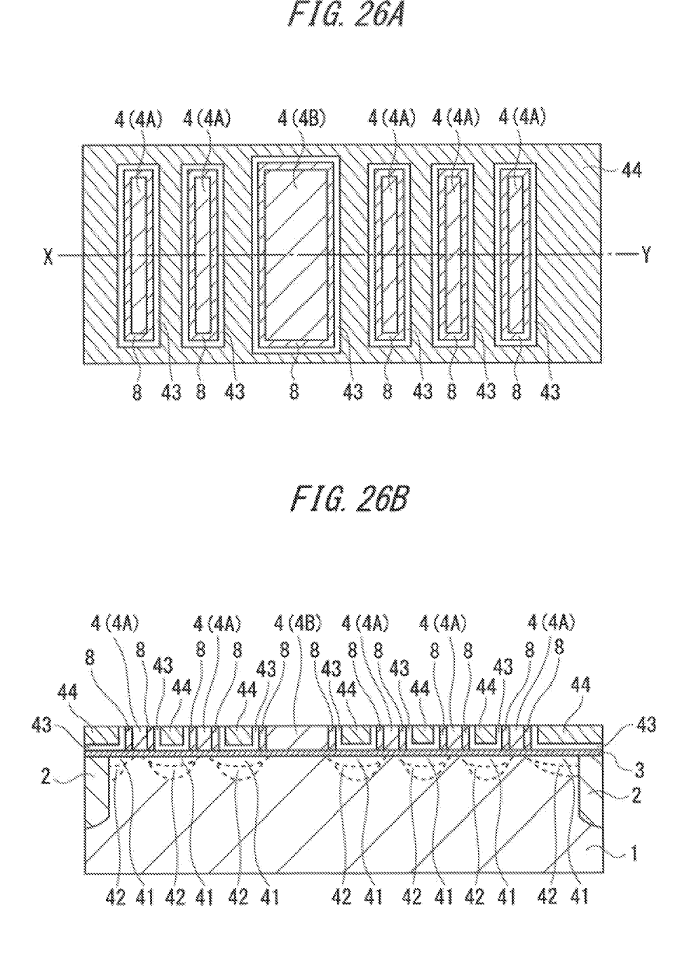

FIG. 26A is a plan view illustrating the manufacturing method of the semiconductor device according to the embodiment 1. FIG. 26B is a cross-sectional view illustrating the manufacturing method of the semiconductor device according to the embodiment 1, and represents a cross section along the single-dot chain line X-Y of FIG. 26A. In steps illustrated in FIGS. 26A and 26B, the hard masks 5 and 6 and upper portions of the sidewalls 8, the contact etch stop layer 43 and the interlayer insulating film 44 are removed by CMP. By performing this removal process, the hard masks 4, the sidewalls 8 and the contact etch stop layer 43 are exposed out of the interlayer insulating film 44.

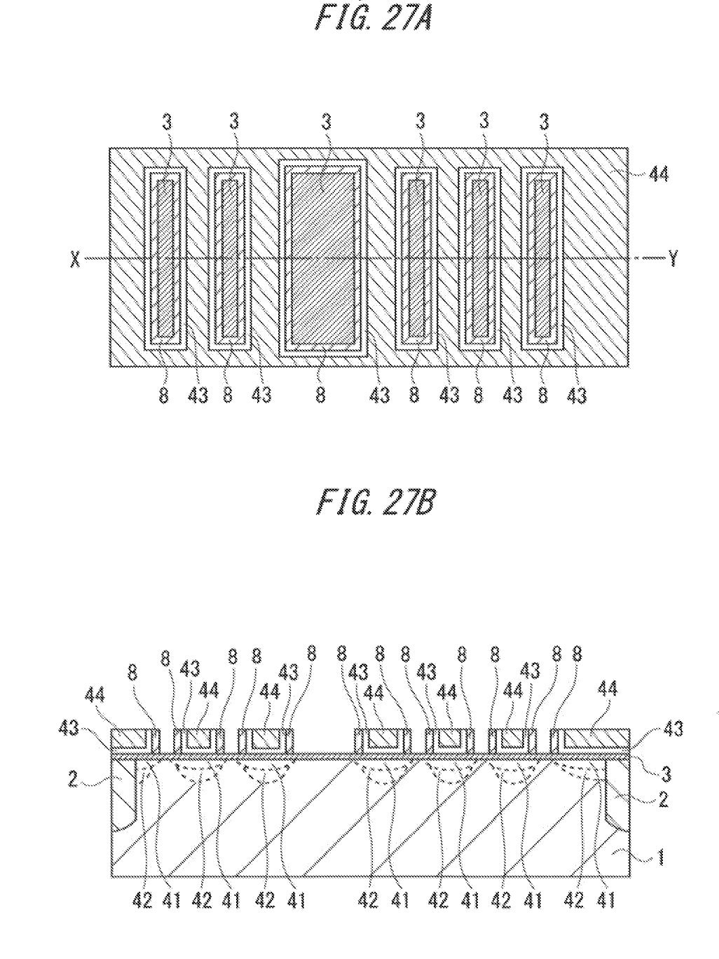

FIG. 27A is a plan view illustrating the manufacturing method of the semiconductor device according to the embodiment 1. FIG. 27B is a cross-sectional view illustrating the manufacturing method of the semiconductor device according to the embodiment 1, and represents a cross section along the single-dot chain line X-Y of FIG. 27A. In steps illustrated in FIGS. 27A and 27B, anisotropic dry etching is performed to remove the dummy gates 4. By removing the dummy gates 4, the silicon dioxide film 3 is exposed out of the sidewalls 8. Anisotropic dry etching is performed using a gas containing, for example, Cl₂, HBr, CF₄ or SF₆.

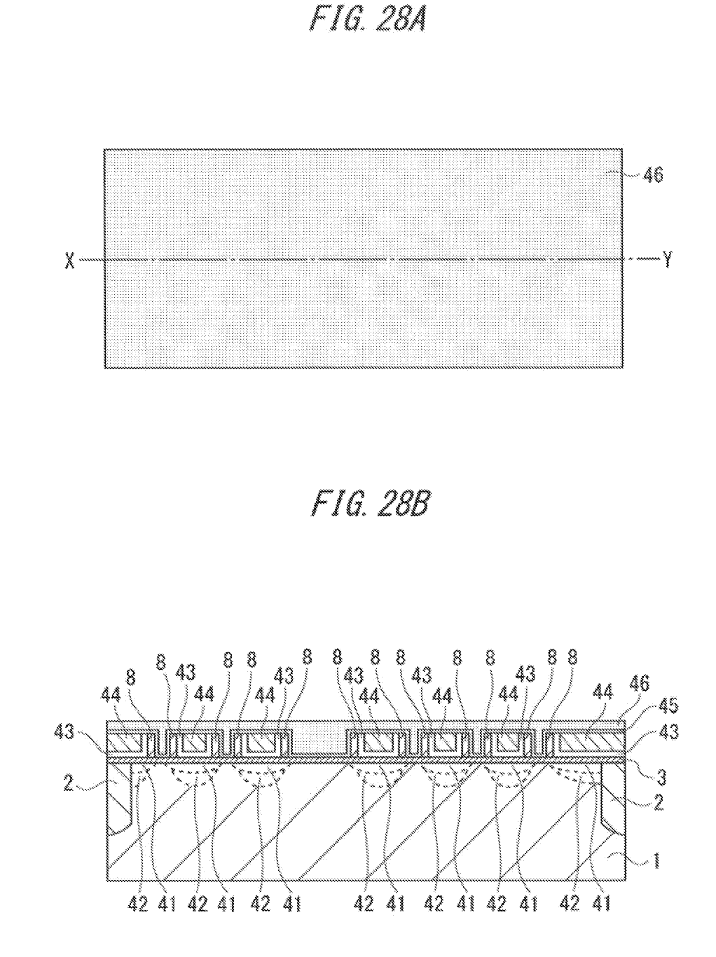

FIG. 28A is a plan view illustrating the manufacturing method of the semiconductor device according to the embodiment 1. FIG. 28B is a cross-sectional view illustrating the manufacturing method of the semiconductor device according to the embodiment 1, and represents a cross section along the single-dot chain line X-Y of FIG. 28A. In steps illustrated in FIGS. 28A and 28B, a gate insulating film 45 is formed on the entire surface of the semiconductor substrate 1 by, for example, a CVD method. Then, a gate electrode metal 46 is formed on the entire surface of the semiconductor substrate 1 by, for example, sputtering. Consequently, the gate insulating film 45 is formed on the silicon dioxide film 3 and on the side surfaces of the sidewalls 8. In addition, the gate electrode metal 46 is buried and formed in spaces surrounded by the sidewalls 8. The gate insulating film 45 is, for example, a single-layered or laminated high-dielectric insulating film of HfO₂, HfSiO, HfAlON, Y₂O₃, ZrO, TiO, TaO or the like. As the gate electrode metal 46, such metal as Ti, Ta, TiN, TaN, W, Cu, Al or Ru is used in the form of a single or laminated layer.

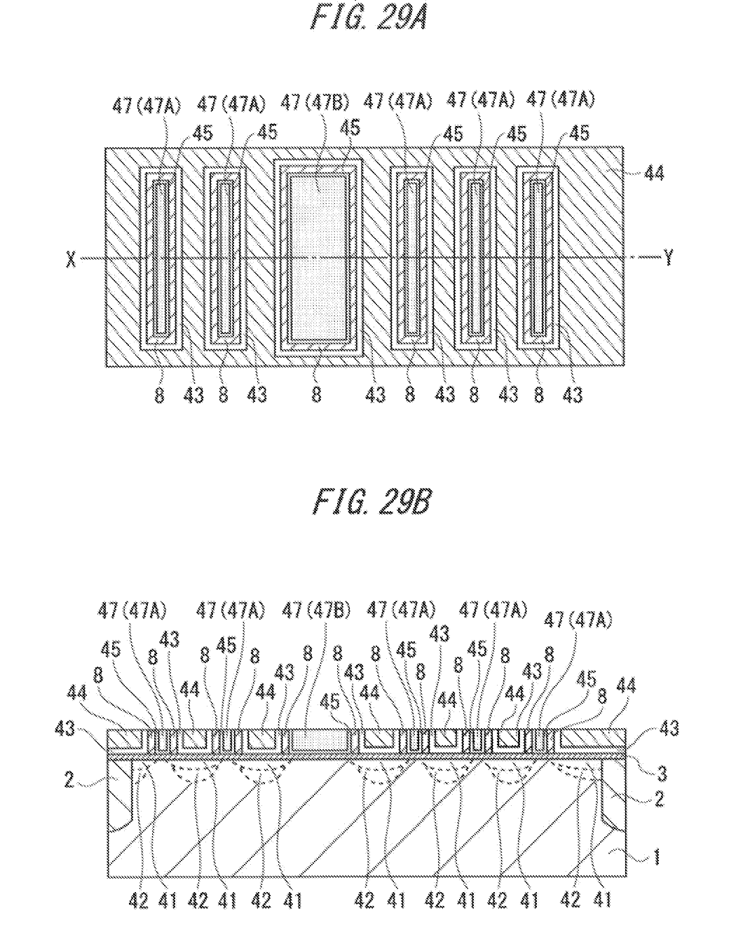

FIG. 29A is a plan view illustrating the manufacturing method of the semiconductor device according to the embodiment 1. FIG. 29B is a cross-sectional view illustrating the manufacturing method of the semiconductor device according to the embodiment 1, and represents a cross section along the single-dot chain line X-Y of FIG. 29A. In steps illustrated in FIGS. 29A and 29B, unneeded surface parts of the gate electrode metal 46 are removed by CMP to segmentalize the gate electrode metal 46, thereby forming a plurality of gate electrodes 47 above the semiconductor substrate 1. Accordingly, the plurality of gate electrodes 47 is formed above the semiconductor substrate 1, such that the lengthwise direction of each gate electrode 47 and the lengthwise direction of the active region of the semiconductor substrate 1 are orthogonal to each other. The plurality of gate electrodes 47 includes gate electrodes 47A smaller in width than a gate electrode 47B and the gate electrode 47B larger in width than the gate electrodes 47A.

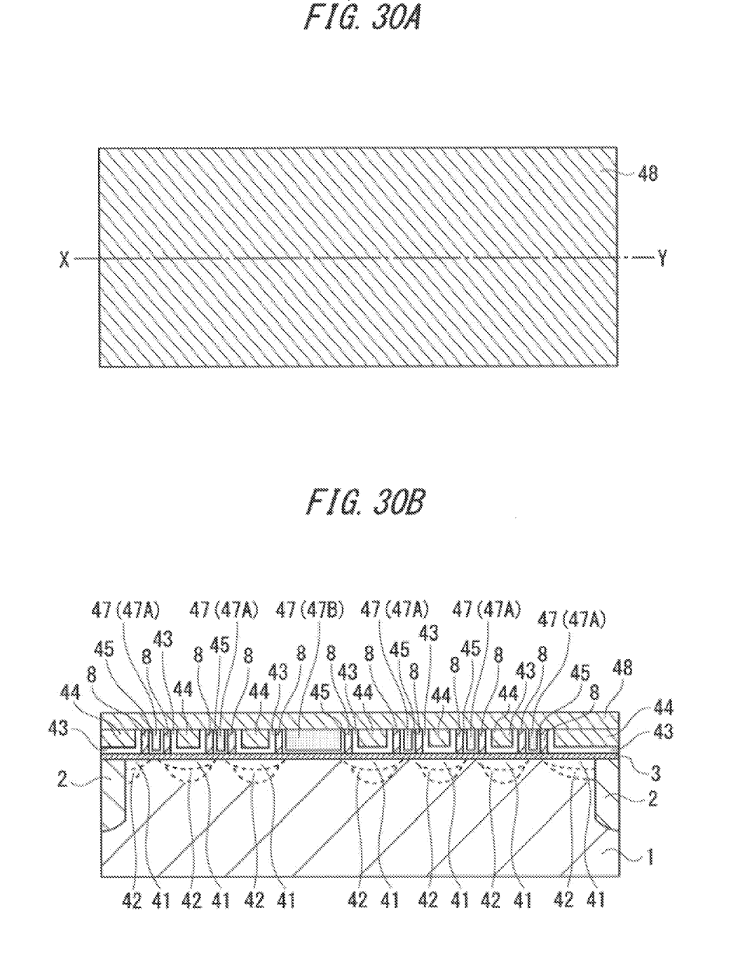

FIG. 30A is a plan view illustrating the manufacturing method of the semiconductor device according to Embodiment 1. FIG. 30B is a cross-sectional view illustrating the manufacturing method of the semiconductor device according to the embodiment 1, and represents a cross section along the single-dot chain line X-Y of FIG. 30A. In steps illustrated in FIGS. 30A and 30B, an interlayer insulating film 48 is formed on the entire surface of the semiconductor substrate 1 by, for example, a CVD method. Consequently, the interlayer insulating film 48 is formed so as to cover the gate electrodes 47. The thickness of the interlayer insulating film 48 is approximately 30 nm. The interlayer insulating film 48 is, for example, a silicon dioxide film. Alternatively, the interlayer insulating film 48 may be formed using, for example, TEOS, USG, BPSG, SiOC, or a porous low-k material.

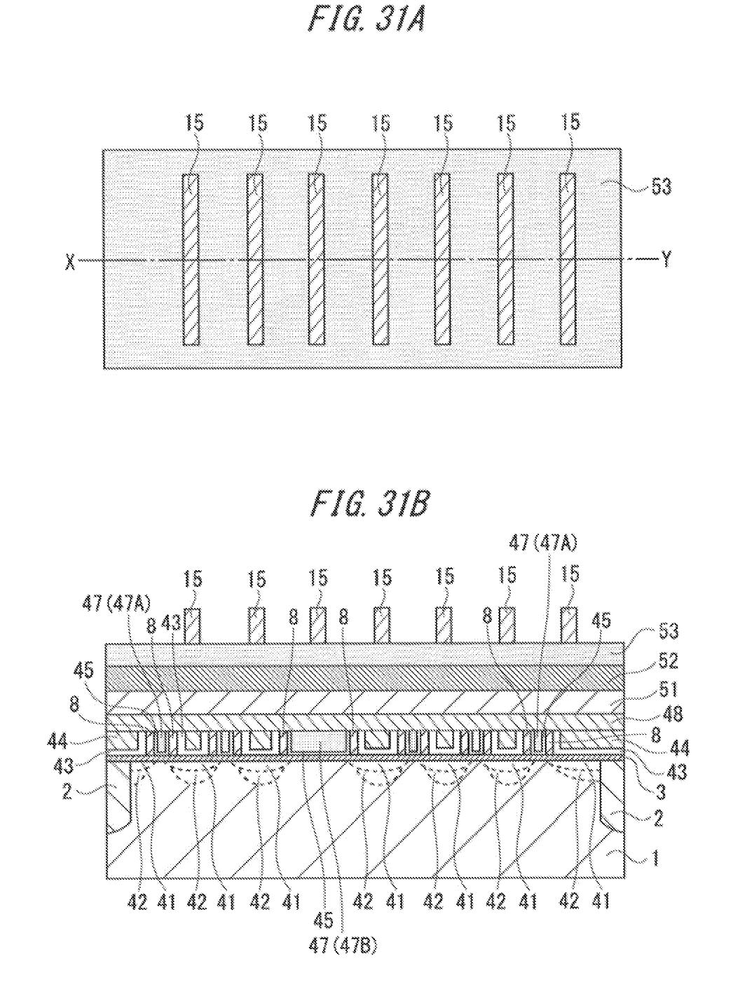

FIG. 31A is a plan view illustrating the manufacturing method of the semiconductor device according to the embodiment 1. FIG. 31B is a cross-sectional view illustrating the manufacturing method of the semiconductor device according to the embodiment 1, and represents a cross section along the single-dot chain line X-Y of FIG. 31A. In steps illustrated in FIGS. 31A and 31B, hard masks 51, 52 and 53 are formed in order on the interlayer insulating film 48. The hard mask 51 is, for example, an amorphous silicon film. The hard mask 52 is, for example, a silicon dioxide film. The hard mask 53 is, for example, a silicon nitride film. The film thickness of each of the hard masks 51, 52 and 53 is, for example, approximately 50 nm. The hard masks 51, 52 and 53 are formed by, for example, a CVD method. In the steps illustrated in FIGS. 31A and 31B, a resist is formed (coated) on the hard mask 53 above the semiconductor substrate 1, and then the mask patterns 31 formed in the photomask 21 illustrated in FIG. 3 are exposure-transferred to the resist using an exposure apparatus. The photomask 21 is placed in a second position above the semiconductor substrate 1. Note that an antireflection film may be formed between the resist and the hard mask 53. In the steps illustrated in FIGS. 31A and 31B, the resist to which the mask patterns 31 of the photomask 21 illustrated in FIG. 3 are transferred is developed to form one or more second resist patterns on the hard mask 53 above the semiconductor substrate 1. The second resist patterns include a plurality of resist patterns 15. Each resist pattern 15 is one example of a second pattern. The plurality of resist patterns 15 is formed on the hard mask 53, so as to align in the plane direction of the semiconductor substrate 1. The plurality of resist patterns 15 is formed on the hard mask 53, such that the lengthwise direction of each resist pattern 15 and the lengthwise direction of the active region of the semiconductor substrate 1 are orthogonal to each other.

The photomask 21 used when forming the resist patterns 15 is used when the resist patterns 11 are formed. In this case, the mask patterns 31 of the photomask 21 are exposure-transferred to the resist by displacing the photomask 21 in a predetermined direction from the first position in which the photomask 21 used when forming the resist patterns 11 is placed, and placing the photomask 21 in the second position. The predetermined direction is a direction corresponding to the lengthwise direction of the active region of the semiconductor substrate 1. In this case, the photomask 21 is displaced so that the position where each resist pattern 15 is formed is shifted by a half pitch from the position where each resist pattern 11 is formed. The half pitch is half the value of the pitch of resist patterns which is a sum of the width of each resist pattern and the distance between adjacent resist patterns. In the example illustrated in FIGS. 31A and 31B, the resist patterns 15 are formed by displacing the photomask 21 rightwards in plan view from the first position in which the photomask 21 used when forming the resist patterns 11 is placed, and placing the photomask 21 in the second position. Without limitation to the example illustrated in FIGS. 31A and 31B, the resist patterns 15 may be formed by displacing the photomask 21 leftwards in plan view from the first position in which the photomask 21 used when forming the resist patterns 11 is placed, and placing the photomask 21 in the second position.

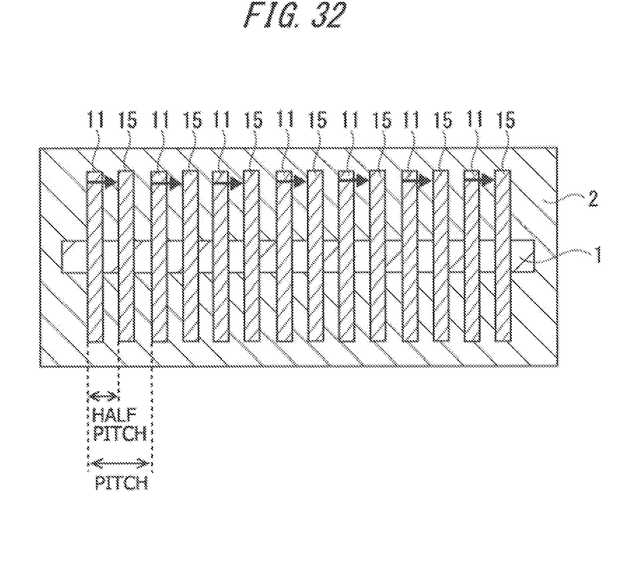

FIG. 32 is a schematic view illustrating the position where each resist pattern 11 is formed and the position where each resist pattern 15 is formed, and is a plan view of the semiconductor substrate 1. FIG. 32 illustrates the semiconductor substrate 1, the element-isolating insulating film 2 and the resist patterns 11 and 15, and other constituent elements are excluded from the illustration. As illustrated in FIG. 32, the resist patterns 11 and 15 are formed above the semiconductor substrate 1, such that the position where each resist pattern 15 is formed is shifted by a half pitch from the position where each resist pattern 11 is formed. Accordingly, the position where each of the plurality of resist patterns 15 is formed is located between the positions where adjacent resist patterns 11, among the plurality of resist patterns 11, are formed.

Here, three examples will be described with regard to the alignment of the photomask 21. First, a first example of alignment will be described. In the first example of alignment, one type of alignment mark A is previously formed in a photomask for element isolation, and one type of alignment mark B is previously formed in the photomask 21. In the steps illustrated in FIGS. 1A and 1B, a record is made of the coordinates of the alignment mark A of the photomask for element isolation when the photomask for element isolation is attached to an exposure apparatus. In the steps illustrated in FIGS. 2A and 2B, the alignment mark B of the photomask 21 is adjusted to the coordinates of the alignment mark A of the photomask for element isolation when the photomask 21 is attached to the exposure apparatus. In the steps illustrated in FIGS. 31A and 31B, the alignment mark B of the photomask 21 is adjusted to the coordinates of the alignment mark A of the photomask for element isolation when the photomask 21 is attached to the exposure apparatus. The photomask 21 is moved by the exposure apparatus, so that the alignment mark B of the photomask 21 is displaced by a half pitch from the coordinates of the alignment mark A of the photomask for element isolation. By this position adjustment, the photomask 21 is displaced so that the position where each resist pattern 15 is formed is shifted by a half pitch from the position where each resist pattern 11 is formed.

Next, a second example of alignment will be described. In the second example of alignment, two types of alignment marks A and B are previously formed in the photomask for element isolation, and two types of alignment marks C and D are previously formed in the photomask 21. The position where the alignment mark A of the photomask for element isolation is formed, and the position where the alignment mark C of the photomask 21 is formed correspond to each other. The position where the alignment mark B of the photomask for element isolation is formed and the position where the alignment mark D of the photomask 21 is formed are displaced by a half pitch from each other. In the steps illustrated in FIGS. 1A and 1B, a record is made of the coordinates of the alignment mark A and B of the photomask for element isolation when the photomask for element isolation is attached to an exposure apparatus. In the steps illustrated in FIGS. 2A and 2B, the alignment mark C of the photomask 21 is adjusted to the coordinates of the alignment mark A of the photomask for element isolation when the photomask 21 is attached to the exposure apparatus. In the steps illustrated in FIGS. 31A and 31B, the alignment mark D of the photomask 21 is adjusted to the coordinates of the alignment mark B of the photomask for element isolation when the photomask 21 is attached to the exposure apparatus. By this position adjustment, the photomask 21 is displaced so that the position where each resist pattern 15 is formed is shifted by a half pitch from the position where each resist pattern 11 is formed.

Next, a third example of alignment will be described. In the third example of alignment, one type of alignment mark A is previously formed in the photomask for element isolation, and two types of alignment marks B and C are previously formed in the photomask 21. In the steps illustrated in FIGS. 1A and 1B, a record is made of the coordinates of the alignment mark A of the photomask for element isolation when the photomask for element isolation is attached to an exposure apparatus. In the steps illustrated in FIGS. 2A and 2B, the alignment mark B of the photomask 21 is adjusted to the coordinates of the alignment mark A of the photomask for element isolation when the photomask 21 is attached to the exposure apparatus. In the steps illustrated in FIGS. 31A and 31B, the coordinates of the alignment mark C of the photomask 21 are adjusted when the photomask 21 is attached to the exposure apparatus. The photomask 21 is moved by the exposure apparatus, so as to be displaced by a half pitch from the coordinates of the alignment mark C of the photomask 21. By this position adjustment, the photomask 21 is displaced so that the position where each resist pattern 15 is formed is shifted by a half pitch from the position where each resist pattern 11 is formed.

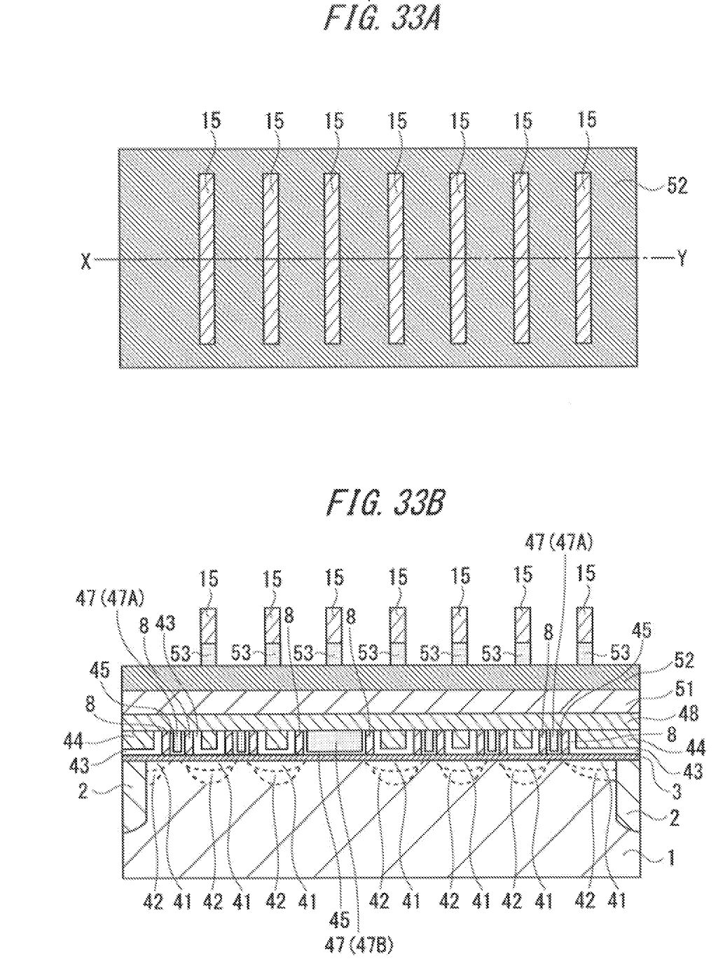

FIG. 33A is a plan view illustrating the manufacturing method of the semiconductor device according to the embodiment 1. FIG. 33B is a cross-sectional view illustrating the manufacturing method of the semiconductor device according to the embodiment 1, and represents a cross section along the single-dot chain line X-Y of FIG. 33A. In steps illustrated in FIGS. 33A and 33B, anisotropic dry etching is performed with the resist patterns 15 as a mask to partially remove and process the hard mask 53. That is, the pattern shapes of the resist patterns 15 are transferred to the hard mask 53 to form a plurality of hard masks 53 on the hard mask 52. Accordingly, the plurality of hard masks 53 is formed on the hard mask 52, such that the lengthwise direction of each hard mask 53 and the lengthwise direction of the active region of the semiconductor substrate 1 are orthogonal to each other. Anisotropic dry etching is performed using a gas containing, for example, CF₄, C₄F₈, CH₂F₂, CHF₃ or CH₃F.

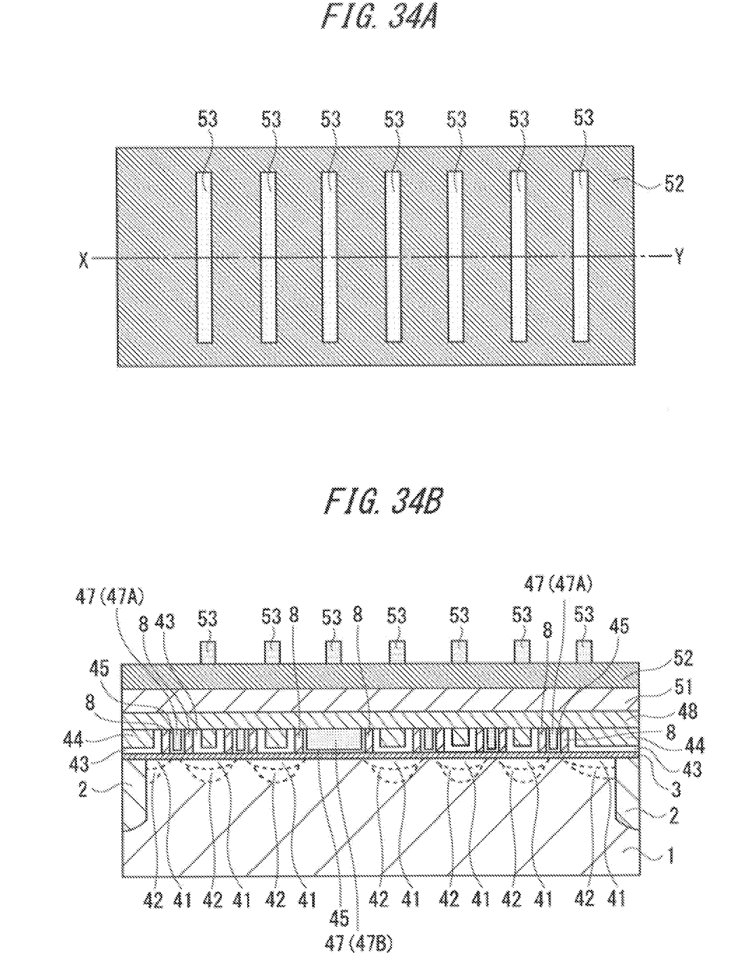

FIG. 34A is a plan view illustrating the manufacturing method of the semiconductor device according to the embodiment 1. FIG. 34B is a cross-sectional view illustrating the manufacturing method of the semiconductor device according to the embodiment 1, and represents a cross section along the single-dot chain line X-Y of FIG. 34A. In steps illustrated in FIGS. 34A and 34B, the resist patterns 15 are removed by, for example, ashing.

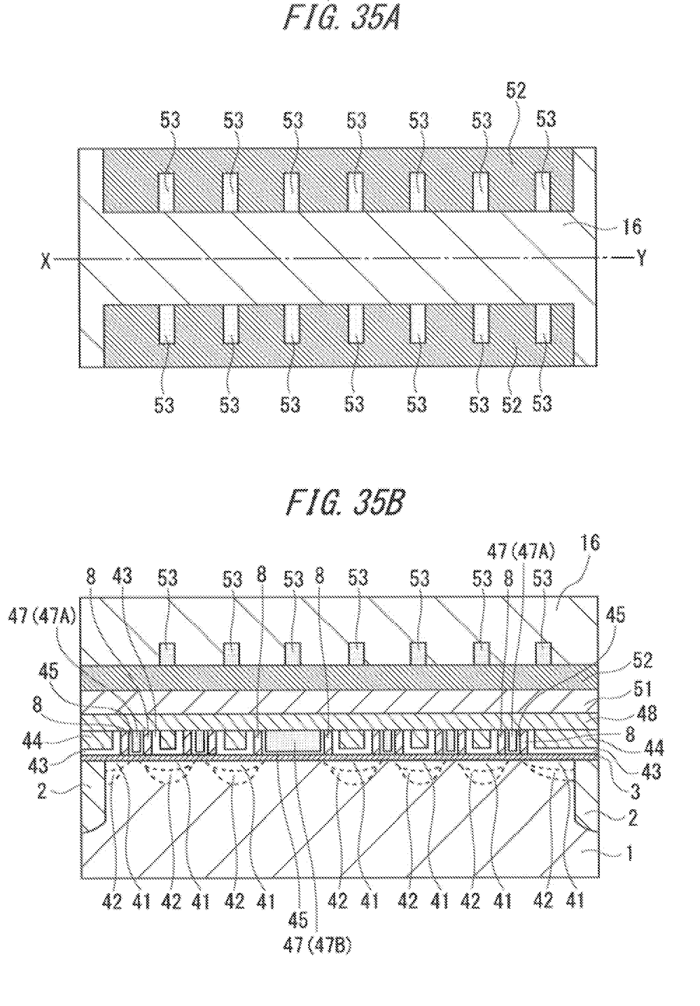

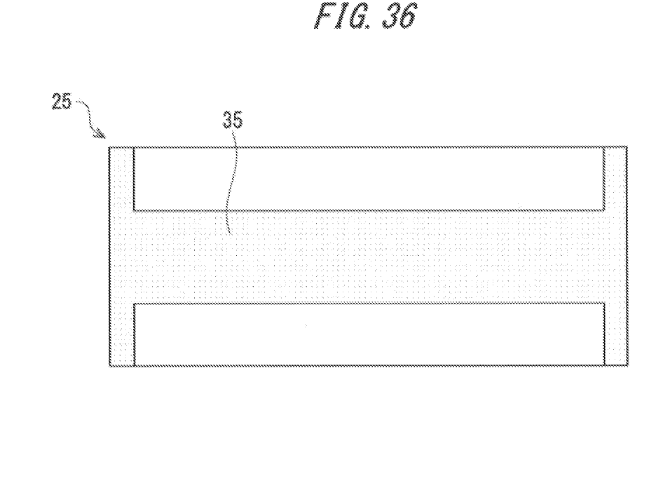

FIG. 35A is a plan view illustrating the manufacturing method of the semiconductor device according to the embodiment 1. FIG. 35B is a cross-sectional view illustrating the manufacturing method of the semiconductor device according to the embodiment 1, and represents a cross section along the single-dot chain line X-Y of FIG. 35A. In steps illustrated in FIGS. 35A and 35B, a resist is formed (coated) on the hard mask 52 above the semiconductor substrate 1, and then a mask pattern 35 formed in a photomask 25 illustrated in FIG. 36 is exposure-transferred to the resist using an exposure apparatus. Note that an antireflection film may be formed between the resist and the hard mask 52. In the steps illustrated in FIGS. 35A and 35B, the resist to which the mask pattern 35 of the photomask 25 is transferred is developed to form a resist pattern 16 on the hard mask 52 above the semiconductor substrate 1.

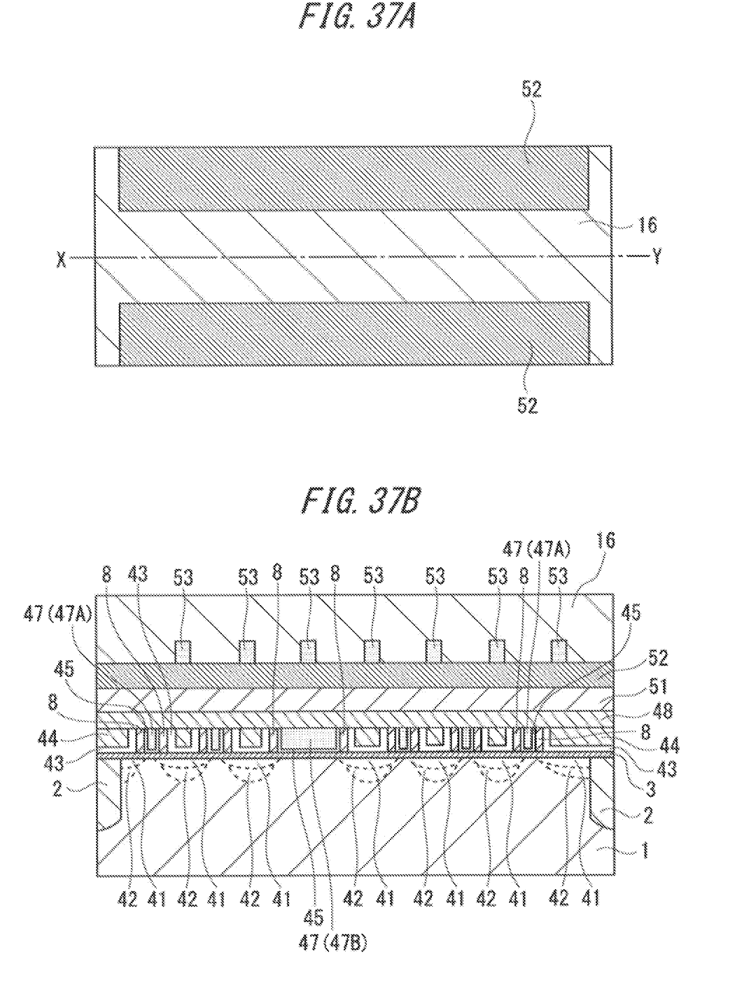

FIG. 37A is a plan view illustrating the manufacturing method of the semiconductor device according to the embodiment 1. FIG. 37B is a cross-sectional view illustrating the manufacturing method of the semiconductor device according to the embodiment 1, and represents a cross section along the single-dot chain line X-Y of FIG. 37A. In steps illustrated in FIGS. 37A and 37B, anisotropic dry etching is performed with the resist pattern 16 as a mask to remove hard masks 53 exposed out of places where the resist pattern 16 is opened. Consequently, both ends of each hard mask 53 are removed, thus reducing the long-side length of each hard mask 53. In this case, the long-side length of each hard mask 53 is smaller than the long-side length of each hard mask 6 formed in the steps illustrated in FIGS. 8A and 8B. Without limitation to this case, the long-side length of each hard mask 53 may be as large as the long-side length of each hard mask 6 or may be larger than the long-side length of each hard mask 6. Anisotropic dry etching is performed using a gas containing, for example, CF₄, C₄F₈, CH₂F₂, CHF₃ or CH₃F.

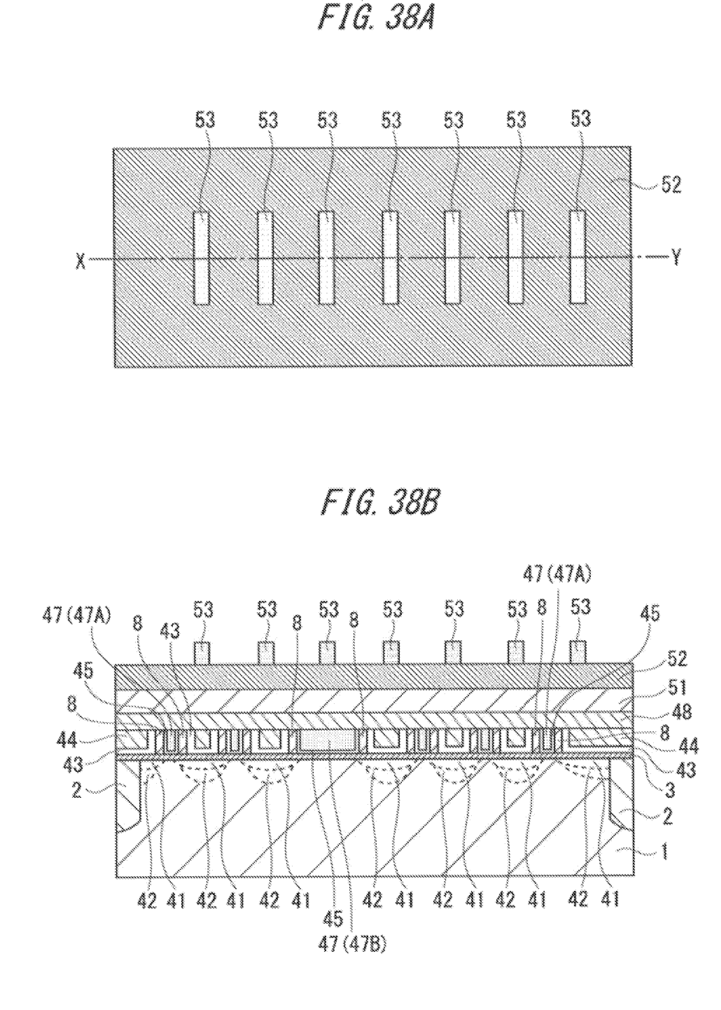

FIG. 38A is a plan view illustrating the manufacturing method of the semiconductor device according to the embodiment 1. FIG. 38B is a cross-sectional view illustrating the manufacturing method of the semiconductor device according to the embodiment 1, and represents a cross section along the single-dot chain line X-Y of FIG. 38A. In steps illustrated in FIGS. 38A and 38B, the resist pattern 16 is removed by, for example, ashing.

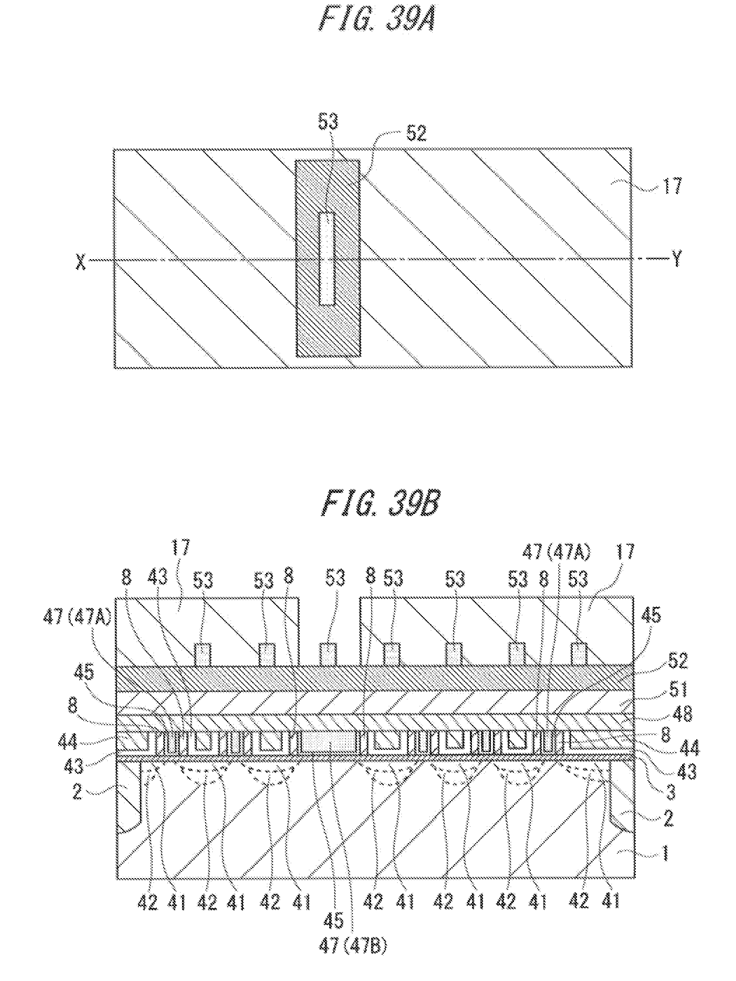

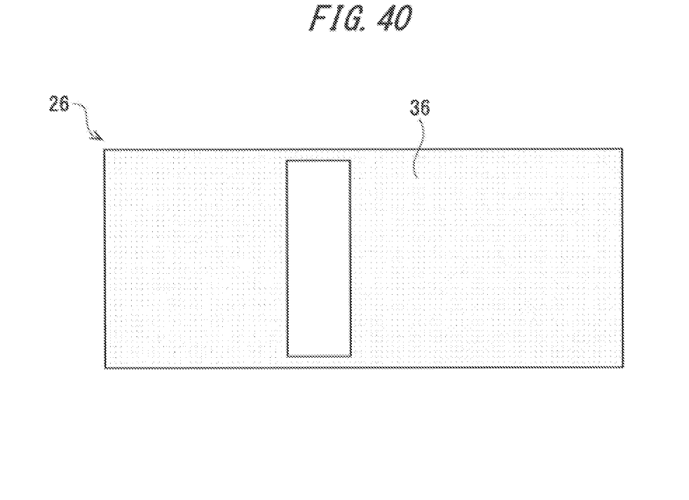

FIG. 39A is a plan view illustrating the manufacturing method of the semiconductor device according to the embodiment 1. FIG. 39B is a cross-sectional view illustrating the manufacturing method of the semiconductor device according to the embodiment 1, and represents a cross section along the single-dot chain line X-Y of FIG. 39A. In steps illustrated in FIGS. 39A and 39B, a resist is formed (coated) on the hard mask 52 above the semiconductor substrate 1, and then a mask pattern 36 formed in a photomask 26 illustrated in FIG. 40 is exposure-transferred to the resist using an exposure apparatus. Note that an antireflection film may be formed between the resist and the hard mask 52. In the steps illustrated in FIGS. 39A and 39B, the resist to which the mask pattern 36 of the photomask 26 is transferred is developed to form a resist pattern 17 on the hard mask 52 above the semiconductor substrate 1.

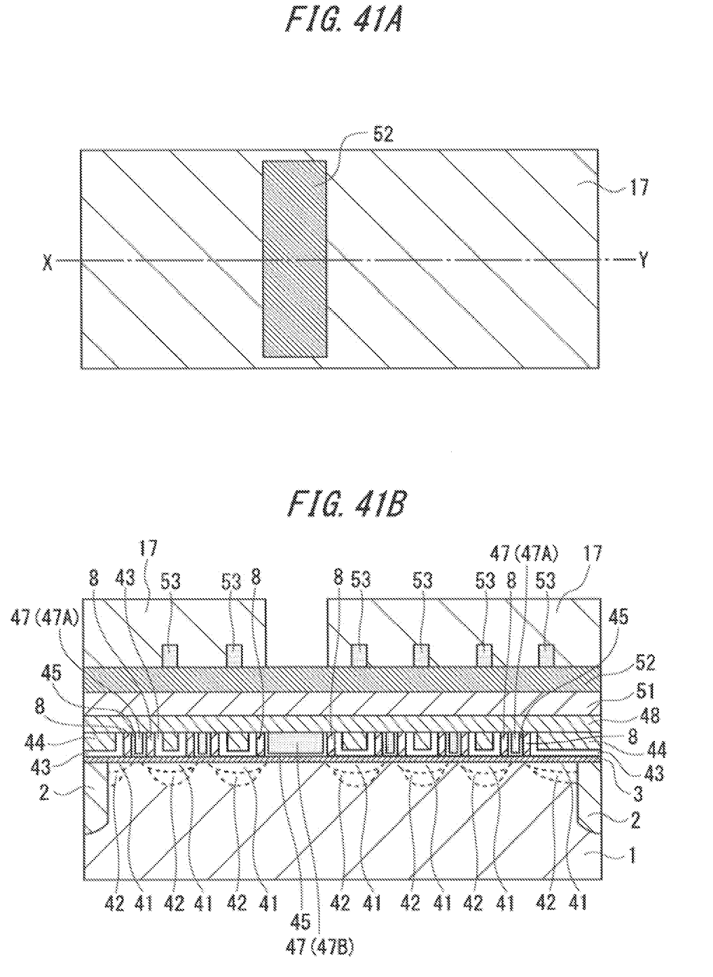

FIG. 41A is a plan view illustrating the manufacturing method of the semiconductor device according to the embodiment 1. FIG. 41B is a cross-sectional view illustrating the manufacturing method of the semiconductor device according to the embodiment 1, and represents a cross section along the single-dot chain line X-Y of FIG. 41A. In steps illustrated in FIGS. 41A and 41B, anisotropic dry etching is performed with the resist pattern 17 as a mask to remove hard masks 53 exposed out of places where the resist pattern 17 is opened. Consequently, at least one hard mask 53 is removed. The hard mask 53 to be removed is one formed above the gate electrode 47B. Anisotropic dry etching is performed using a gas containing, for example, CF₄, C₄F₈, CH₂F₂, CHF₃ or CH₃F.

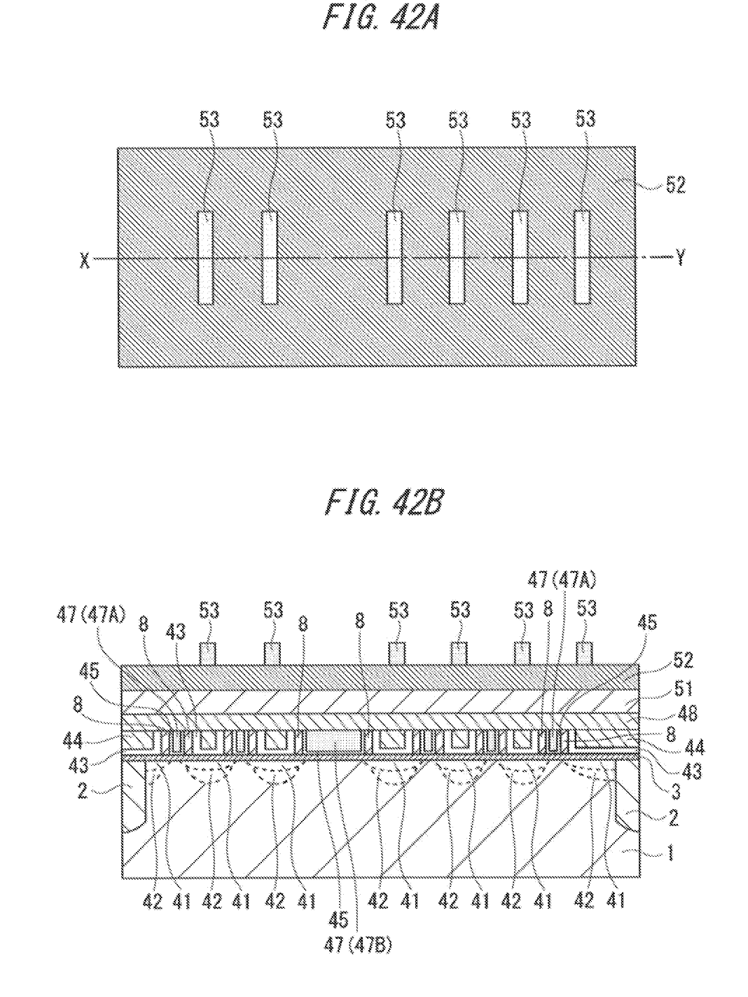

FIG. 42A is a plan view illustrating the manufacturing method of the semiconductor device according to the embodiment 1. FIG. 42B is a cross-sectional view illustrating the manufacturing method of the semiconductor device according to the embodiment 1, and represents a cross section along the single-dot chain line X-Y of FIG. 42A. In steps illustrated in FIGS. 42A and 42B, the resist pattern 17 is removed by, for example, ashing.

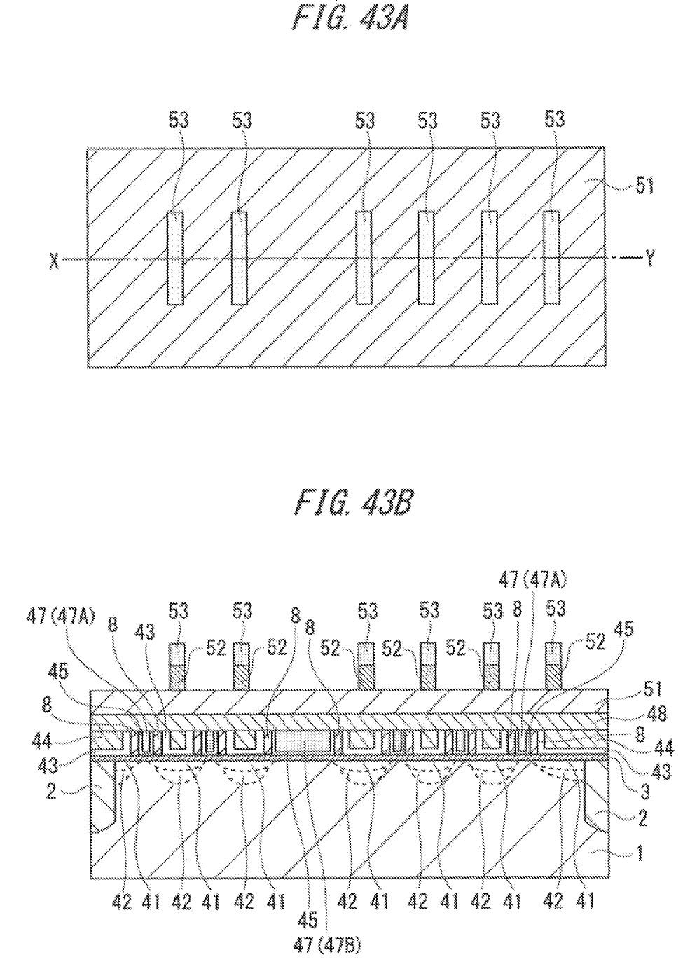

FIG. 43A is a plan view illustrating the manufacturing method of the semiconductor device according to the embodiment 1. FIG. 43B is a cross-sectional view illustrating the manufacturing method of the semiconductor device according to the embodiment 1, and represents a cross section along the single-dot chain line X-Y of FIG. 43A. In steps illustrated in FIGS. 43A and 43B, anisotropic dry etching is performed with the hard masks 53 as a mask to partially remove the hard mask 52 and process the hard masks 53. That is, the pattern shapes of the hard masks 53 are transferred to the hard mask 52 to form a plurality of hard masks 52 on the hard mask 51. Accordingly, the plurality of hard masks 52 is formed on the hard mask 51, such that the lengthwise direction of each hard mask 52 and the lengthwise direction of the active region of the semiconductor substrate 1 are orthogonal to each other. Anisotropic dry etching is performed using a gas containing, for example, CF₄, C₄F₈, CH₂F₂, CHF₃ or CH₃F.

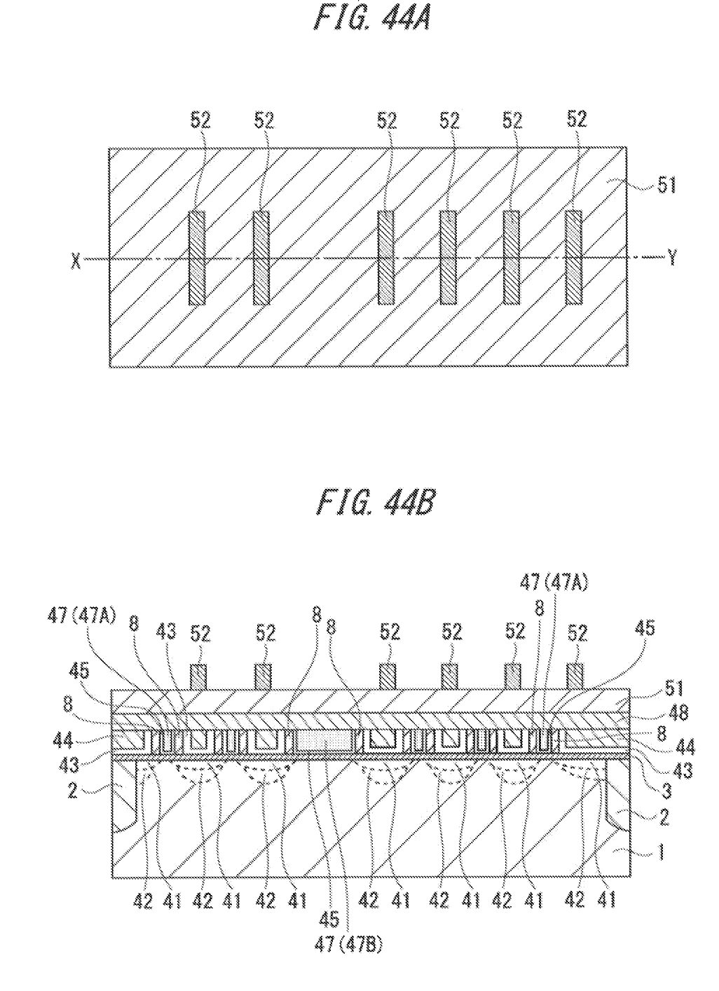

FIG. 44A is a plan view illustrating the manufacturing method of the semiconductor device according to the embodiment 1. FIG. 44B is a cross-sectional view illustrating the manufacturing method of the semiconductor device according to the embodiment 1, and represents a cross section along the single-dot chain line X-Y of FIG. 44A. In steps illustrated in FIGS. 44A and 44B, anisotropic dry etching is performed to remove the hard masks 53. Anisotropic dry etching is performed using a gas containing, for example, CF₄, C₄F₈, CH₂F₂, CHF₃ or CH₃F.

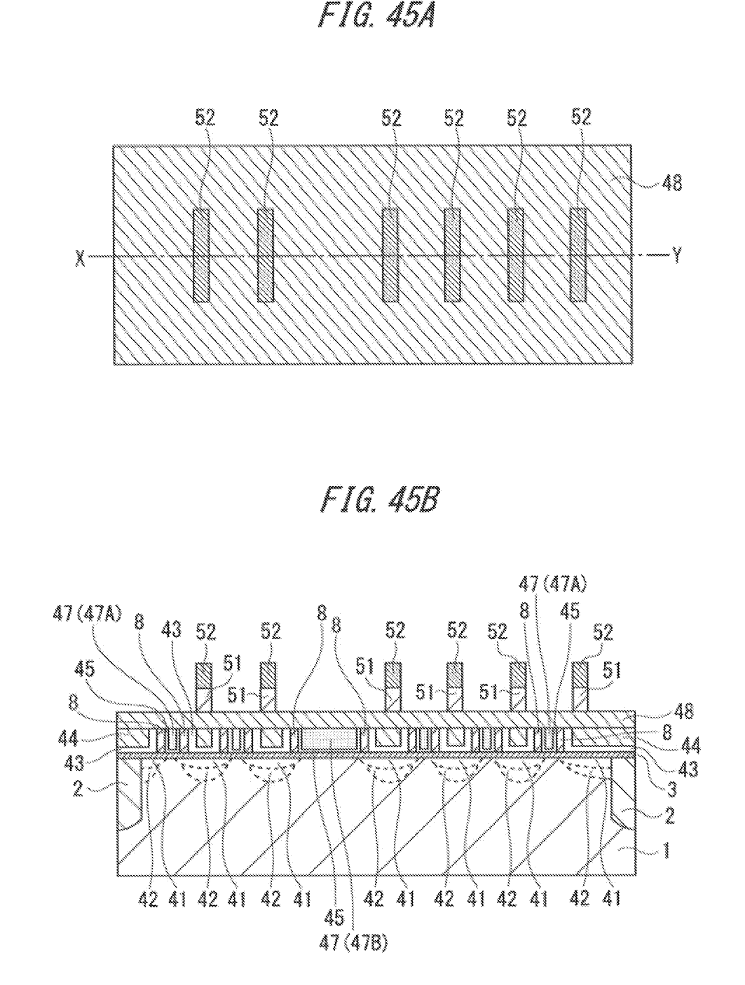

FIG. 45A is a plan view illustrating the manufacturing method of the semiconductor device according to the embodiment 1. FIG. 45B is a cross-sectional view illustrating the manufacturing method of the semiconductor device according to the embodiment 1, and represents a cross section along the single-dot chain line X-Y of FIG. 45A. In steps illustrated in FIGS. 45A and 45B, anisotropic dry etching is performed with the hard masks 52 as a mask to partially remove and process the hard mask 51. That is, the pattern shapes of the hard masks 52 are transferred to the hard mask 51 to form a plurality of hard masks 51 on the interlayer insulating film 48. Accordingly, the plurality of hard masks 51 is formed on the interlayer insulating film 48, such that the lengthwise direction of each hard mask 51 and the lengthwise direction of the active region of the semiconductor substrate 1 are orthogonal to each other. Anisotropic dry etching is performed using a gas containing, for example, Cl₂, HBr, CF₄ or SF₆.

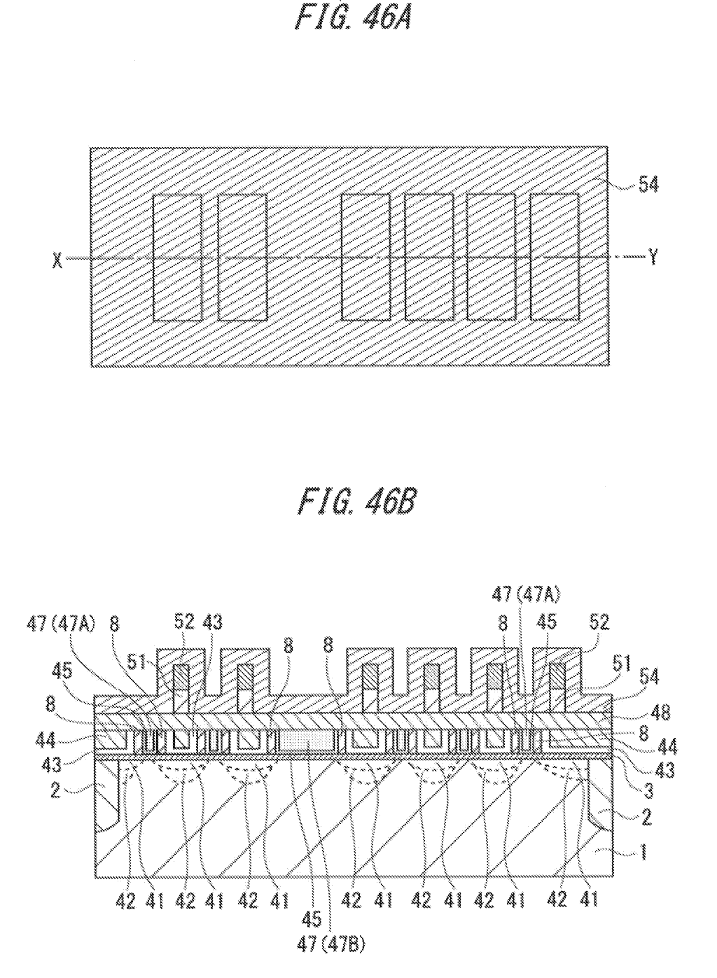

FIG. 46A is a plan view illustrating the manufacturing method of the semiconductor device according to the embodiment 1. FIG. 46B is a cross-sectional view illustrating the manufacturing method of the semiconductor device according to the embodiment 1, and represents a cross section along the single-dot chain line X-Y of FIG. 46A. In steps illustrated in FIGS. 46A and 46B, a hard mask 54 is formed on the interlayer insulating film 48 by, for example, a CVD method. The film thickness of the hard mask 54 is, for example, approximately 20 nm. The hard mask 54 is, for example, a silicon nitride film. The hard mask 54 may be a silicon dioxide film or a high-dielectric insulating film, such as an HfO₂, HfSiO, HfAlON, Y₂O₃, ZrO, TiO or TaO film.

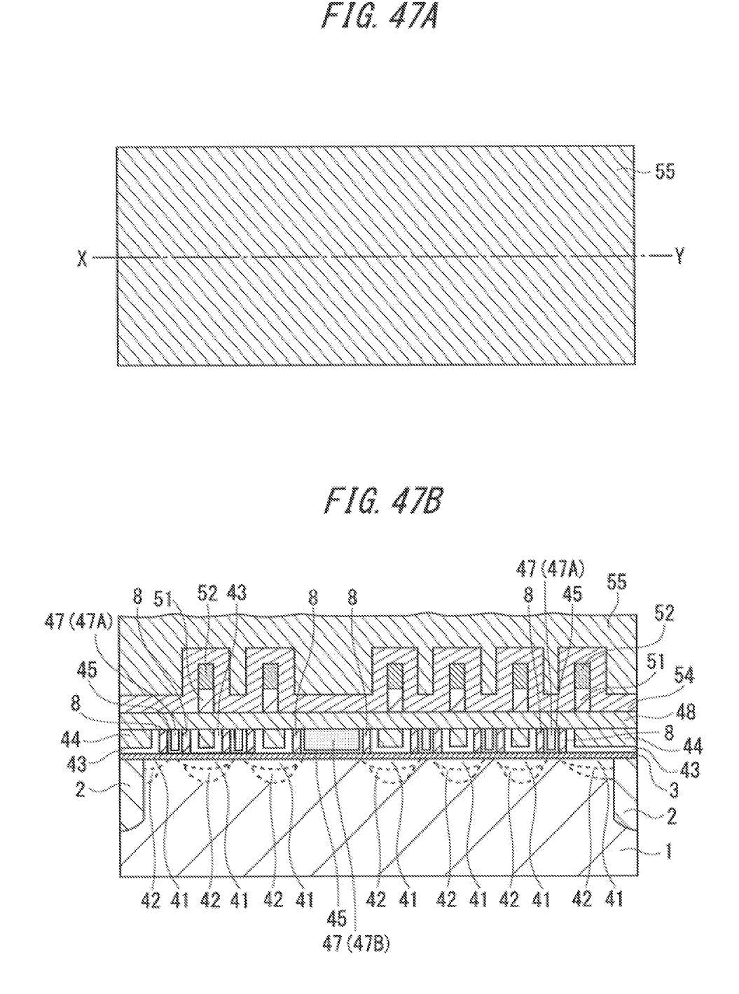

FIG. 47A is a plan view illustrating the manufacturing method of the semiconductor device according to the embodiment 1. FIG. 47B is a cross-sectional view illustrating the manufacturing method of the semiconductor device according to the embodiment 1, and represents a cross section along the single-dot chain line X-Y of FIG. 47A. In steps illustrated in FIGS. 47A and 47B, an interlayer insulating film 55 is formed on the hard mask 54 by, for example, a CVD method. The interlayer insulating film 55 is, for example, a silicon dioxide film. Alternatively, the interlayer insulating film 55 may be formed using, for example, TEOS, USG, BPSG, SiOC, or a porous low-k material.

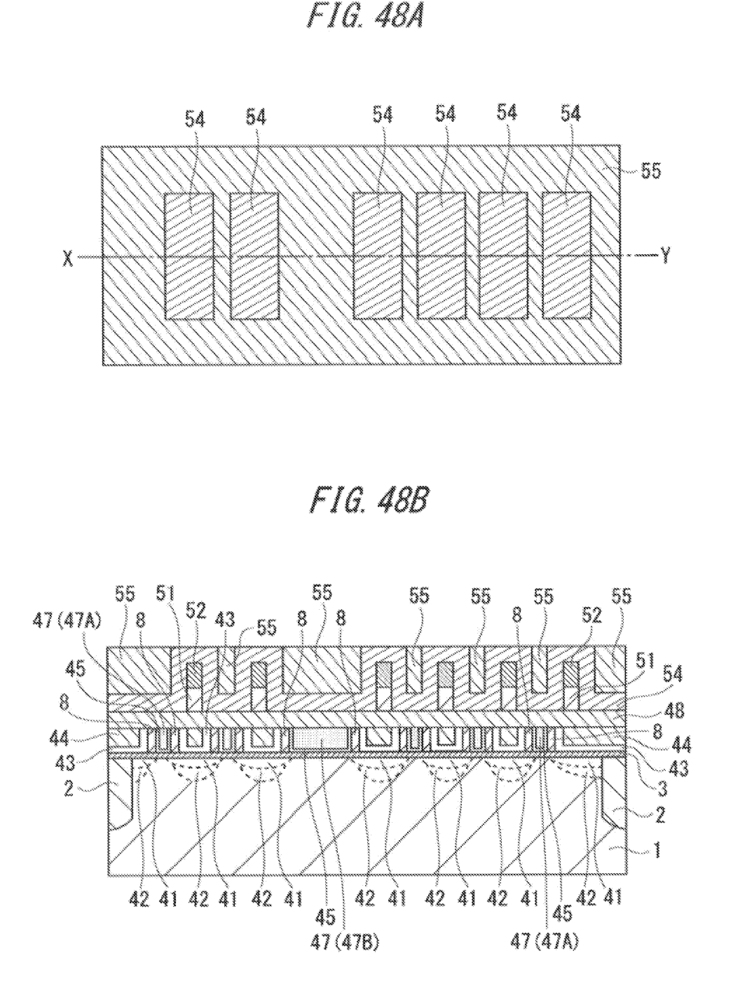

FIG. 48A is a plan view illustrating the manufacturing method of the semiconductor device according to the embodiment 1. FIG. 48B is a cross-sectional view illustrating the manufacturing method of the semiconductor device according to the embodiment 1, and represents a cross section along the single-dot chain line X-Y of FIG. 48A. In steps illustrated in FIGS. 48A and 48B, the interlayer insulating film 55 is planarized by CMP to remove an upper portion of the interlayer insulating film 55, thereby exposing the hard masks 54 out of the interlayer insulating film 55.

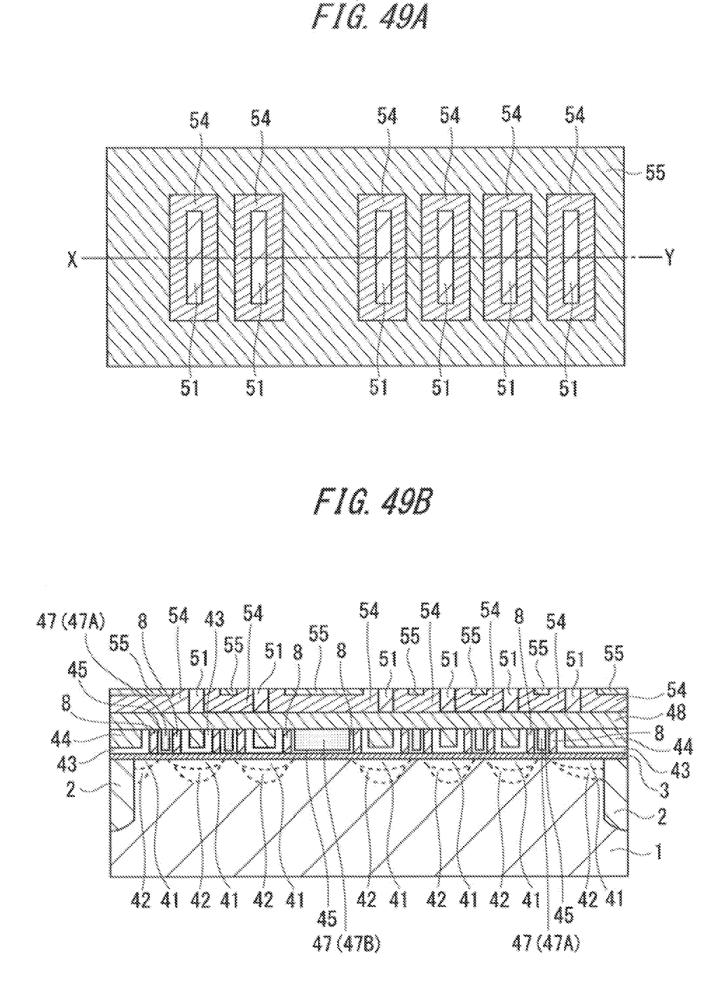

FIG. 49A is a plan view illustrating the manufacturing method of the semiconductor device according to the embodiment 1. FIG. 49B is a cross-sectional view illustrating the manufacturing method of the semiconductor device according to the embodiment 1, and represents a cross section along the single-dot chain line X-Y of FIG. 49A. In steps illustrated in FIGS. 49A and 49B, the hard masks 52 and the upper portions of the hard masks 54 and the interlayer insulating film 55 are removed by CMP. By performing this removal process, the hard masks 51 are exposed out of the hard masks 54.

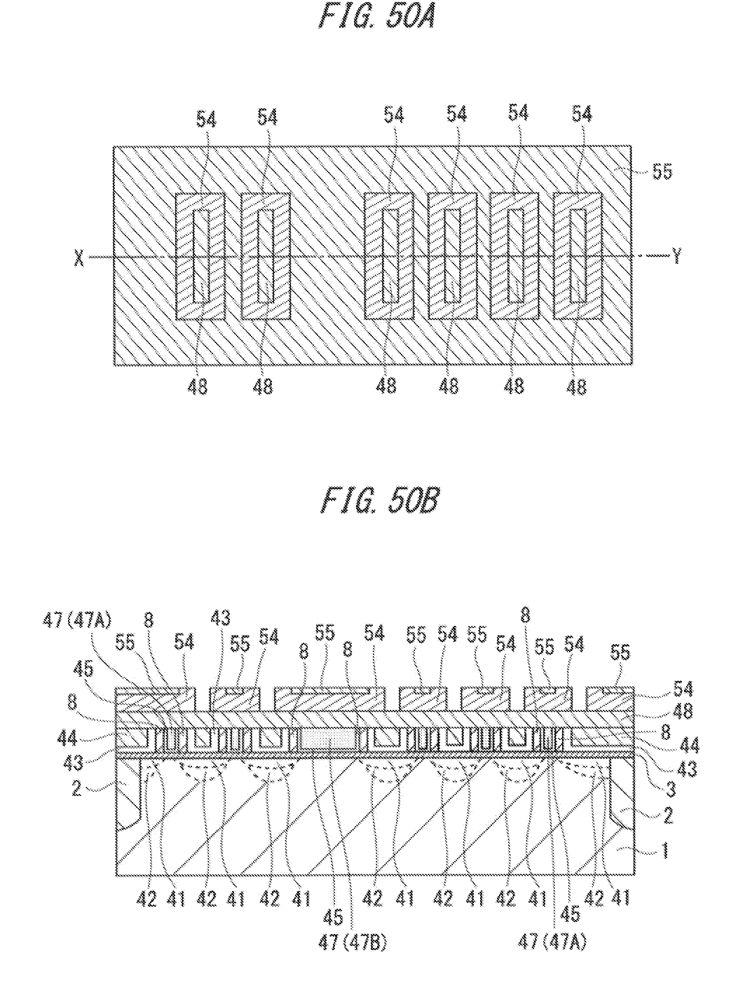

FIG. 50A is a plan view illustrating the manufacturing method of the semiconductor device according to the embodiment 1. FIG. 50B is a cross-sectional view illustrating the manufacturing method of the semiconductor device according to the embodiment 1, and represents a cross section along the single-dot chain line X-Y of FIG. 50A. In steps illustrated in FIGS. 50A and 50B, anisotropic dry etching is performed to remove the hard masks 51. By removing the hard masks 51, the interlayer insulating film 48 is exposed out of the hard masks 54. Anisotropic dry etching is performed using a gas containing, for example, Cl₂, HBr, CF₄ or SF₆.

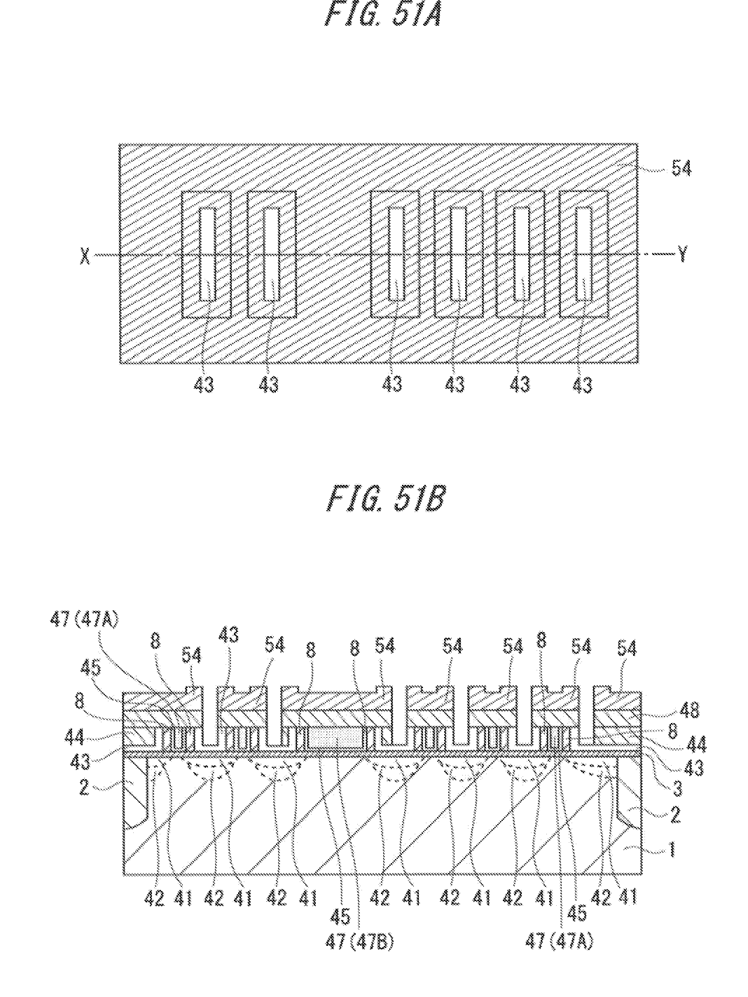

FIG. 51A is a plan view illustrating the manufacturing method of the semiconductor device according to the embodiment 1. FIG. 51B is a cross-sectional view illustrating the manufacturing method of the semiconductor device according to the embodiment 1, and represents a cross section along the single-dot chain line X-Y of FIG. 51A. In steps illustrated in FIGS. 51A and 51B, anisotropic dry etching is performed on the interlayer insulating films 44 and 48 with the hard mask 54 as a mask to form trenches in the interlayer insulating films 44 and 48, so as to reach to the contact etch stop layers 43. The interlayer insulating films 55 on the hard masks 54 are removed as the result of anisotropic dry etching being performed. Anisotropic dry etching is performed using a gas containing, for example, CF₄, C₄F₈, CH₂F₂, CHF₃ or CH₃F.

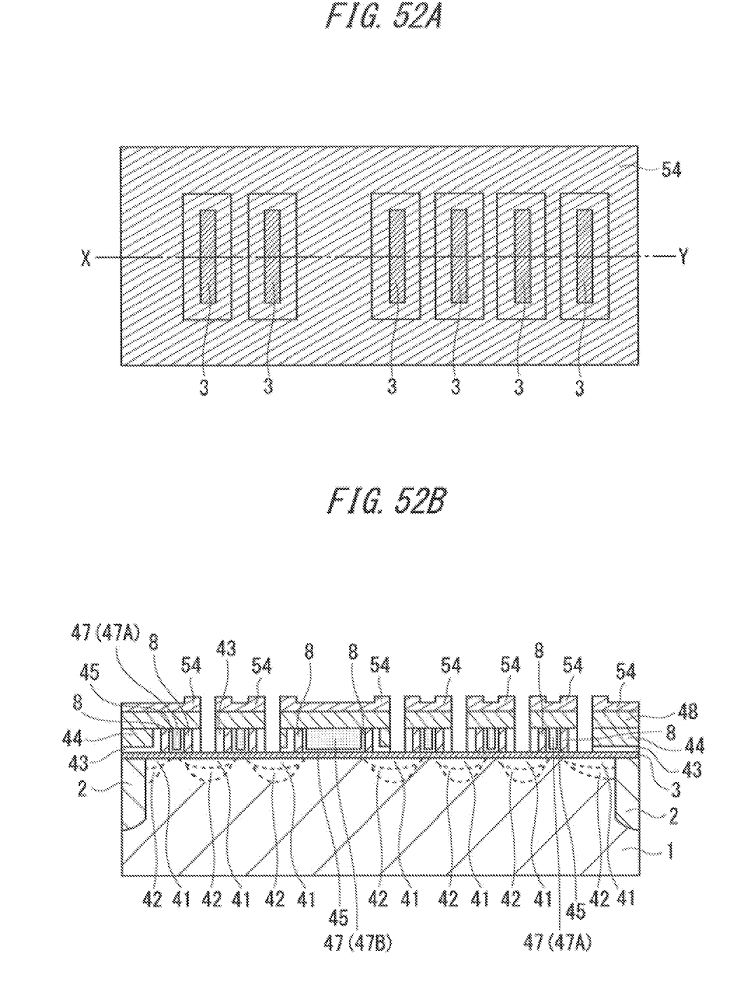

FIG. 52A is a plan view illustrating the manufacturing method of the semiconductor device according to the embodiment 1. FIG. 52B is a cross-sectional view illustrating the manufacturing method of the semiconductor device according to the embodiment 1, and represents a cross section along the single-dot chain line X-Y of FIG. 52A. In steps illustrated in FIGS. 52A and 52B, anisotropic dry etching is performed on the contact etch stop layers 43 with the hard masks 54 as a mask to form trenches in the contact etch stop layers 43, so as to reach to the silicon dioxide film 3. By forming the trenches in the contact etch stop layer 43, the silicon dioxide film 3 is exposed out of the contact etch stop layer 43. Anisotropic dry etching is performed using a gas containing, for example, CF₄, C₄F₈, CH₂F₂, CHF₃ or CH₃F.

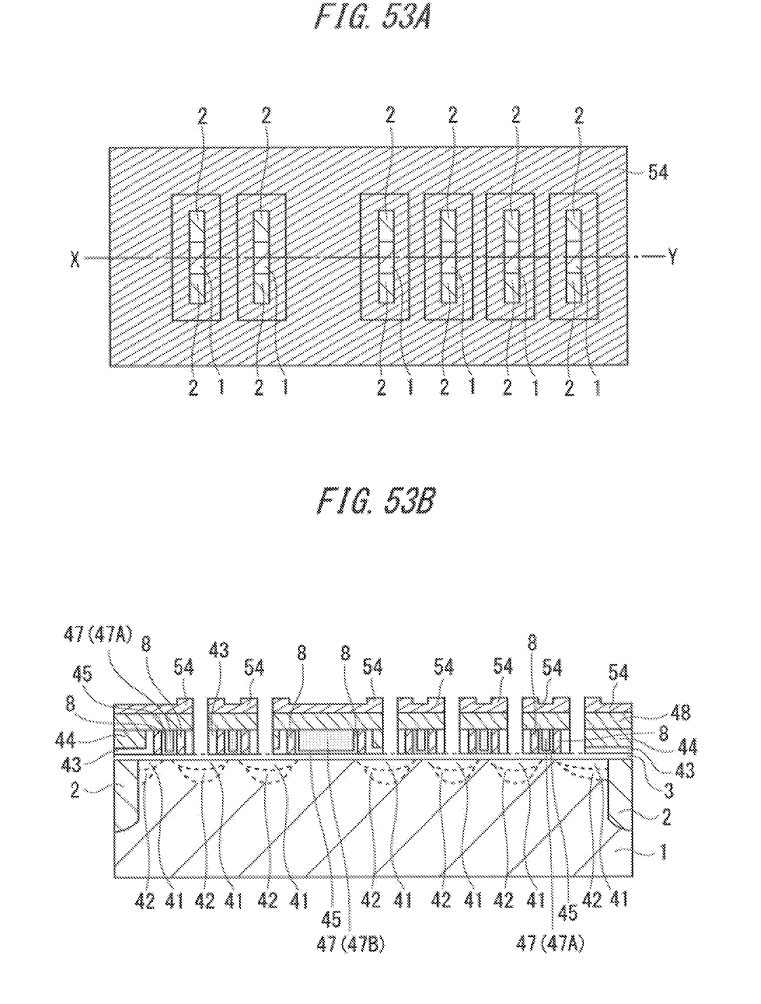

FIG. 53A is a plan view illustrating the manufacturing method of the semiconductor device according to the embodiment 1, where the plan view is taken through the silicon dioxide film 3 illustrated in FIG. 52A. FIG. 53B is a cross-sectional view illustrating the manufacturing method of the semiconductor device according to the embodiment 1, and represents a cross section along the single-dot chain line X-Y of FIG. 53A. FIG. 53B illustrates a cross-sectional view taken through the silicon dioxide film 3 illustrated FIG. 52B.

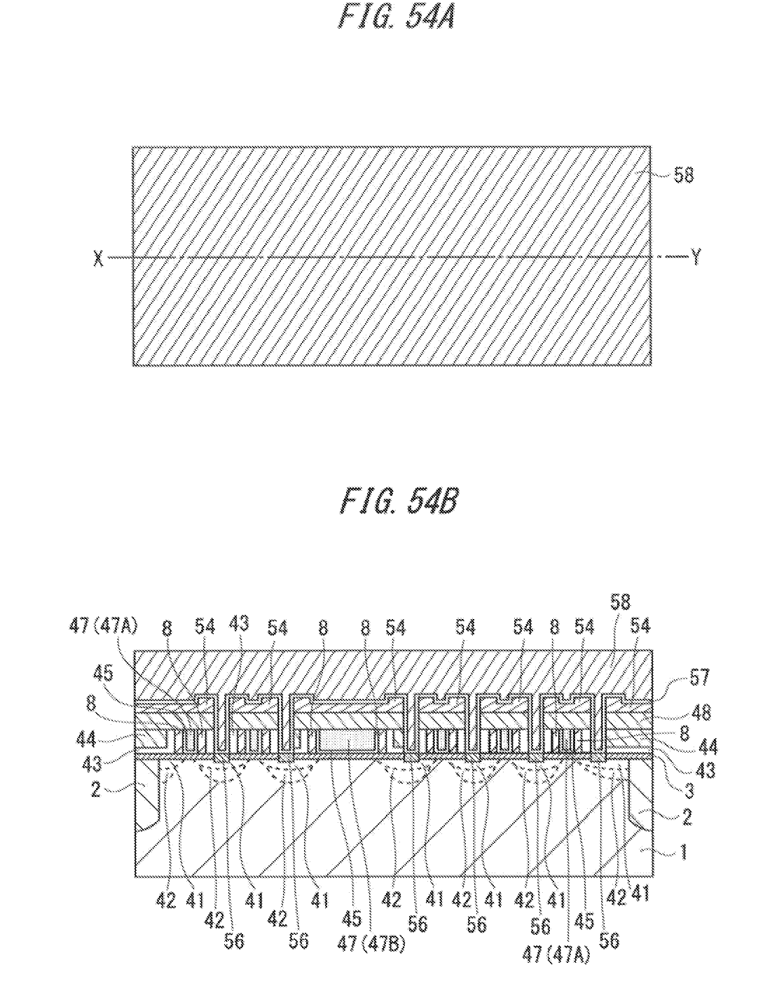

FIG. 54A is a plan view illustrating the manufacturing method of the semiconductor device according to the embodiment 1. FIG. 54B is a cross-sectional view illustrating the manufacturing method of the semiconductor device according to the embodiment 1, and represents a cross section along the single-dot chain line X-Y of FIG. 54A. In steps illustrated in FIGS. 54A and 54B, dry etching or solution treatment using HF or the like is performed to remove portions of the silicon dioxide film 3 exposed out of the contact etch stop layer 43. In the steps illustrated in FIGS. 54A and 54B, metal is deposited on surfaces of the semiconductor substrate 1 exposed out of the silicon dioxide film 3 and heat-treated to form silicides 56 on the surfaces of the semiconductor substrate 1. The metal deposited on the surfaces of the semiconductor substrate 1 is, for example, Ni, Co, Ti, Ru, W, Ta or the like. Each silicide 56 is, for example, WSi, TiSi, CoSi, NiSi, TaSi, RuSi or the like. In the steps illustrated in FIGS. 54A and 54B, barrier metal 57 is deposited and source-drain electrode metal 58 is buried and formed in the trenches formed in the interlayer insulating films 44 and 48 and the contact etch stop layer 43. The barrier metal 57 is, for example, Ti, TiN, Ru, Ta or the like. The source-drain electrode metal 58 is, for example, W, Cu, Al or the like. Alternatively, SiGe, Ge or the like may be buried in the surfaces of the semiconductor substrate 1 before the silicides 56 are formed in the semiconductor substrate 1, thereby forming semiconductor layers on the surfaces of the semiconductor substrate 1.

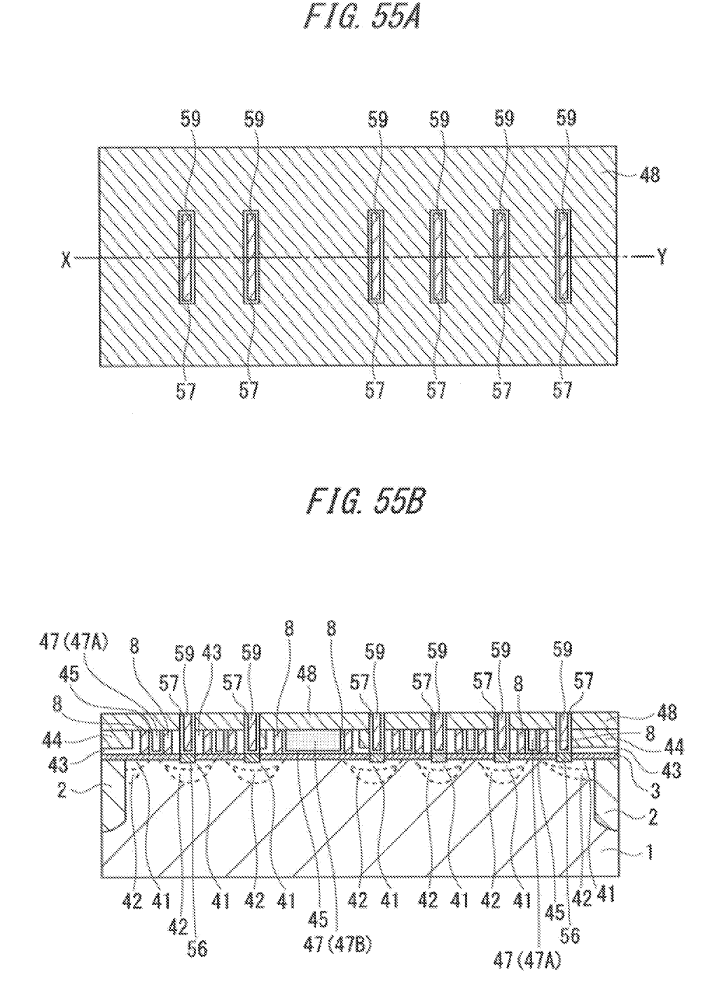

FIG. 55A is a plan view illustrating the manufacturing method of the semiconductor device according to the embodiment 1. FIG. 55B is a cross-sectional view illustrating the manufacturing method of the semiconductor device according to the embodiment 1, and represents a cross section along the single-dot chain line X-Y of FIG. 55A. In steps illustrated in FIGS. 55A and 55B, unneeded surface parts of the source-drain electrode metal 58 are removed by CMP to segmentalize the source-drain electrode metal 58, thereby forming a plurality of source-drain electrodes 59 above the semiconductor substrate 1. After wiring lines are formed on the interlayer insulating film 48, a desired back-end process is performed and thereby the semiconductor device is manufactured.

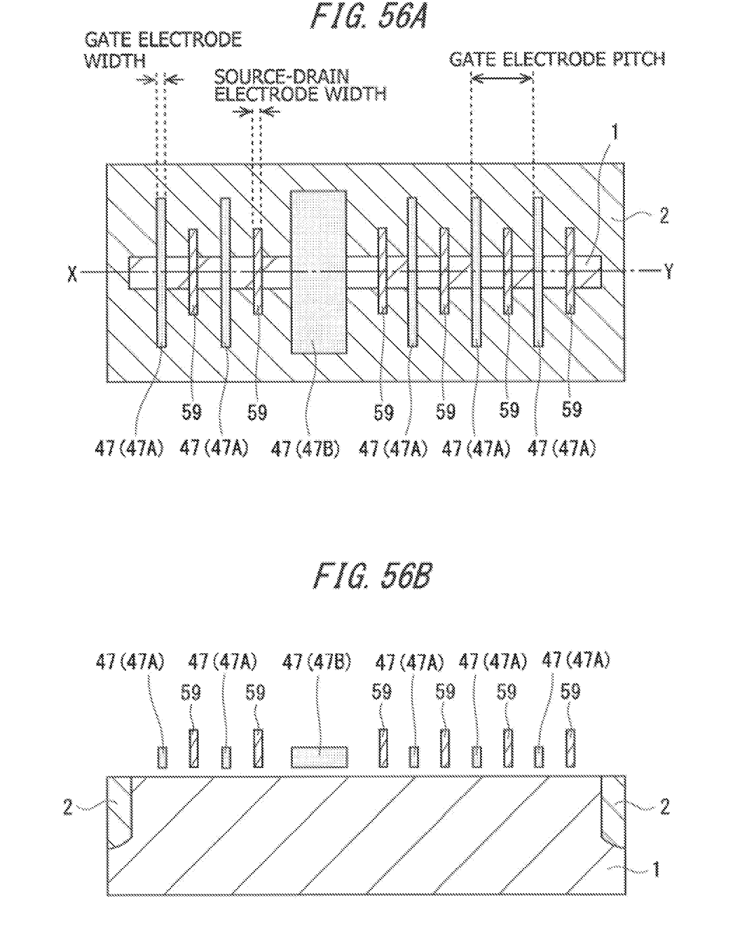

FIG. 56A is a plan view illustrating the manufacturing method of the semiconductor device according to the embodiment 1. FIG. 56B is a cross-sectional view illustrating the semiconductor device according to the embodiment 1, and represents a cross section along the single-dot chain line X-Y of FIG. 56A. FIGS. 56A and 56B illustrate the semiconductor substrate 1, the element-isolating insulating film 2, the gate electrodes 47A and 47B, and the source-drain electrodes 59, and other constituent elements are excluded from the illustration.

A plurality of gate electrodes 47A is lined up regularly at a gate electrode pitch (the pitch of the gate electrodes 47A) and arranged above the semiconductor substrate 1. The gate electrode 47B is located above the semiconductor substrate 1, so as to be positioned between two gate electrodes 47A adjacent to each other in the short-side width direction (widthwise direction) thereof. A plurality of source-drain electrodes 59 is lined up regularly at the gate electrode pitch and arranged above the semiconductor substrate 1. Each two source-drain electrodes 59 are arranged above the semiconductor substrate 1, so as to sandwich one gate electrode 47A in the short-side width direction thereof. Accordingly, each gate electrode 47A is arranged above the semiconductor substrate 1, so as to be positioned between two adjacent source-drain electrodes 59. Two source-drain electrodes 59 are arranged above the semiconductor substrate 1, so as to sandwich one gate electrode 47B in the short-side width direction thereof. Accordingly, the gate electrode 47B is arranged above the semiconductor substrate 1, so as to be positioned between two adjacent source-drain electrodes 59.

In the example cited in the embodiment 1, a drain electrode 59 is not formed on one side (left side in the example illustrated in FIGS. 56A and 56B) of one gate electrode 47A (the leftmost gate electrode 47A in the example illustrated in FIGS. 56A and 56B), among the plurality of gate electrodes 47A lined up and arranged above the semiconductor substrate 1. In the example illustrated in FIGS. 56A and 56B, a drain electrode 59 is formed on the right side of the rightmost gate electrode 47A. The short-side width of the gate electrode 47B is an integer multiple of the gate electrode pitch (equal to the pitch in FIGS. 56A and 56B). The widths of the gate electrodes 47A and 47B may be varied within a predetermined range by means of layout or photomask corrections.

Conventionally, two photomasks are used to form a resist pattern for gate electrodes and a resist pattern for source-drain electrodes. In some cases, a resist pattern for gate electrodes and a resist pattern for source-drain electrodes are formed in a plurality of places above a semiconductor substrate. In these cases, the distance between the resist pattern for gate electrodes and the resist pattern for source-drain electrodes differs depending on a pattern-forming position above the semiconductor substrate due to the effects of distortion or surface roughness in the photomasks.

According to the embodiment 1, the gate electrodes 47A are formed above the semiconductor substrate 1 using the resist patterns 11 formed by exposure-transferring the mask patterns 31 of the photomask 21 to the resist coated on surfaces above the semiconductor substrate 1. In addition, the source-drain electrodes 59 are formed above the semiconductor substrate 1 using the resist patterns 15 formed by exposure-transferring the mask patterns 31 of the photomask 21 to the resist coated on surfaces above the semiconductor substrate 1. The resist patterns 15 are formed by displacing the photomask 21, so that the positions where each resist pattern 11 and each resist pattern 15 are formed are shifted by a half pitch from each other. As described above, the resist patterns 11 used when forming the gate electrodes 47A and the resist patterns 15 used when forming the source-drain electrodes 59 are formed using one photomask 21.

According to the embodiment 1, the distance between the resist patterns 11 and 15 to be formed in a plurality of places above the semiconductor substrate 1 can be kept constant, even if any distortion or surface roughness is present in a photomask, by forming the resist patterns 11 and 15 using one photomask 21. That is, the resist patterns 11 and 15 can be precisely formed above the semiconductor substrate 1 even if any distortion or surface roughness is present in the photomask. Consequently, the distance between each of the gate electrodes 47A and each of the source-drain electrodes 59 to be formed in a plurality of places above the semiconductor substrate 1 can be kept constant even if any distortion or surface roughness is present in the photomask. That is, the gate electrodes 47A and the source-drain electrodes 59 can be precisely formed above the semiconductor substrate 1 even if any distortion or surface roughness is present in the photomask. Accordingly, it is possible to prevent electrical short-circuiting between each gate electrode 47A and each source-drain electrode 59 to be formed above the semiconductor substrate 1. In addition, it is possible to hold down the cost of manufacturing photomasks since the gate electrodes 47A and the source-drain electrodes 59 can be formed using one photomask.

### Embodiment 2

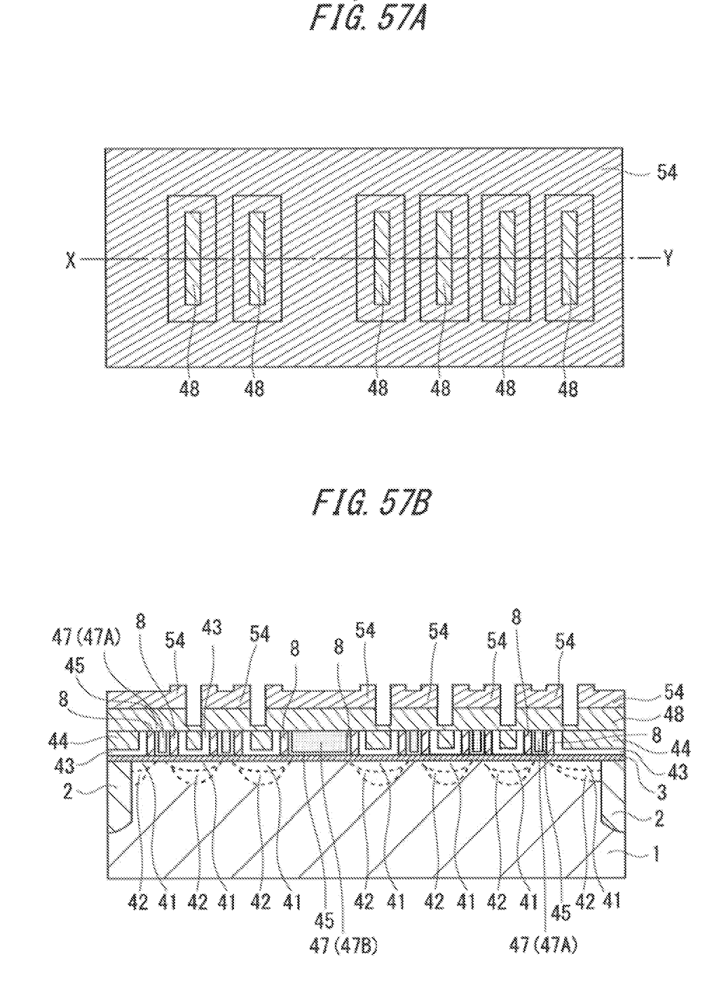

A semiconductor device and a manufacturing method of the semiconductor device according to the embodiment 2 will be described with reference to FIGS. 57A to 62B. The embodiment 2 will be described by citing, as an example, a semiconductor device provided with a MOS transistor which is one example of a semiconductor element. The same steps as those illustrated in FIGS. 1A to 50B in the embodiment 1 are performed, but different steps are performed thereafter in the manufacturing method of the semiconductor device according to the embodiment 2.

FIG. 57A is a plan view illustrating the manufacturing method of the semiconductor device according to the embodiment 2. FIG. 57B is a cross-sectional view illustrating the manufacturing method of the semiconductor device according to the embodiment 2, and represents a cross section along the single-dot chain line X-Y of FIG. 57A. Steps illustrated in FIGS. 57A and 57B follows after the same steps as those of the embodiment 1 illustrated in FIGS. 1A to 50B are performed. In the steps illustrated in FIGS. 57A and 57B, anisotropic dry etching is performed on the interlayer insulating film 48 with the hard mask 54 as a mask to form trenches in the interlayer insulating film 48, so as to reach to midway points of the film in the thickness direction thereof. The interlayer insulating films 55 on the hard masks 54 are removed as the result of anisotropic dry etching being performed. Anisotropic dry etching is performed using a gas containing, for example, CF₄, C₄F₈, CH₂F₂, CHF₃ or CH₃F.

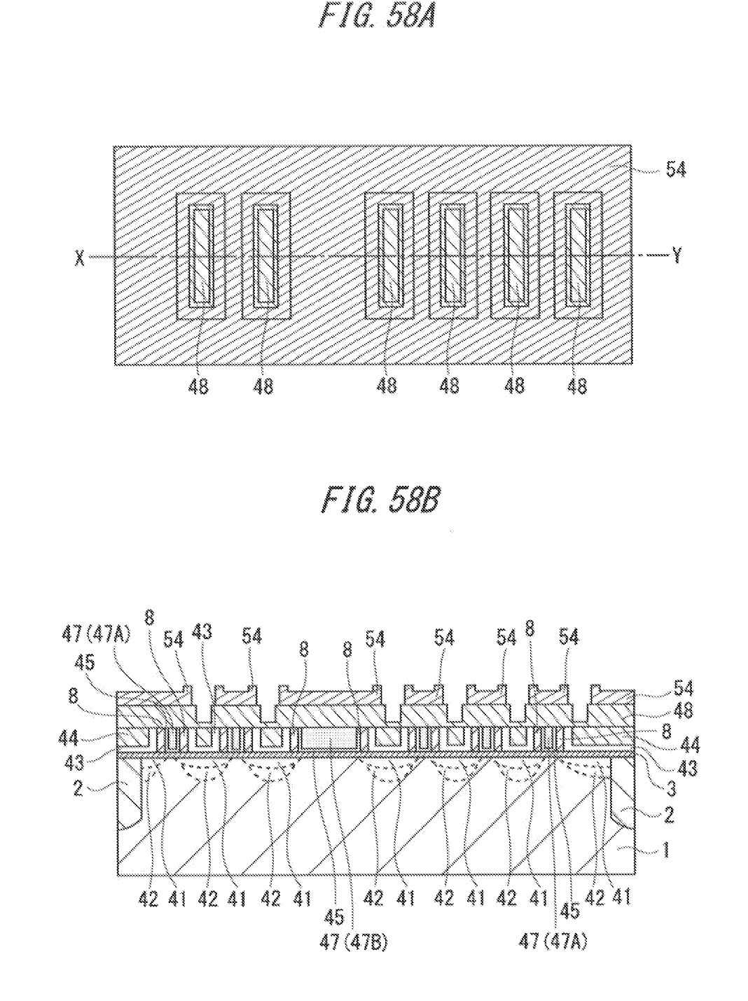

FIG. 58A is a plan view illustrating the manufacturing method of the semiconductor device according to the embodiment 2. FIG. 58B is a cross-sectional view illustrating the manufacturing method of the semiconductor device according to the embodiment 2, and represents a cross section along the single-dot chain line X-Y of FIG. 58A. In steps illustrated in FIGS. 58A and 58B, isotropic etching, such as chemical dry etching, is performed to widen the openings of the hard mask 54.

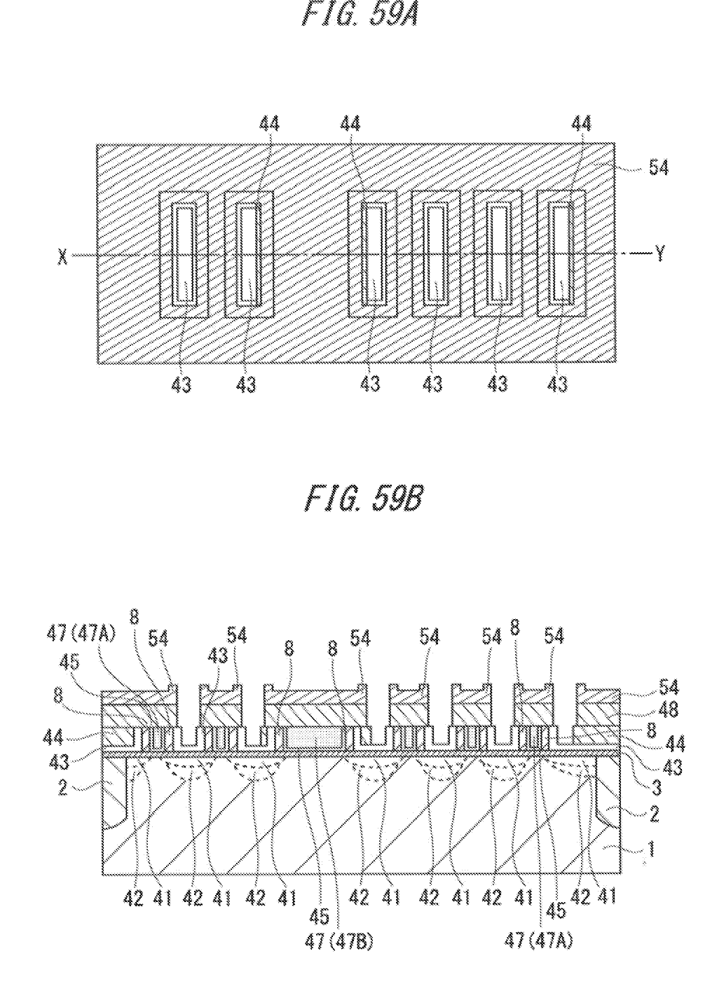

FIG. 59A is a plan view illustrating the manufacturing method of the semiconductor device according to the embodiment 2. FIG. 59B is a cross-sectional view illustrating the manufacturing method of the semiconductor device according to the embodiment 2, and represents a cross section along the single-dot chain line X-Y of FIG. 59A. In steps illustrated in FIGS. 59A and 59B, anisotropic dry etching is performed on the interlayer insulating films 44 and 48 with the hard masks 54 as a mask to form trenches in the interlayer insulating films 44 and 48, so as to reach to the contact etch stop layer 43. Anisotropic dry etching is performed using a gas containing, for example, CF₄, C₄F₈, CH₂F₂, CHF₃ or CH₃F.

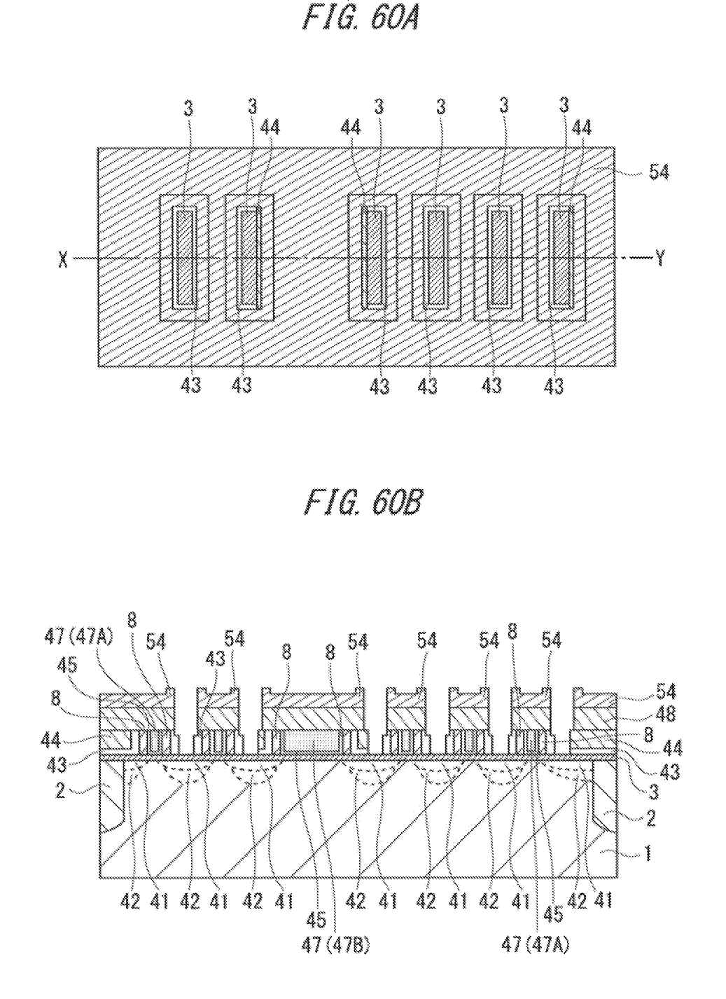

FIG. 60A is a plan view illustrating the manufacturing method of the semiconductor device according to the embodiment 2. FIG. 60B is a cross-sectional view illustrating the manufacturing method of the semiconductor device according to the embodiment 2, and represents a cross section along the single-dot chain line X-Y of FIG. 60A. In steps illustrated in FIGS. 60A and 60B, anisotropic dry etching is performed on the contact etch stop layer 43 with the hard masks 54 as a mask to form trenches in the contact etch stop layer 43, so as to reach to the silicon dioxide film 3. The silicon dioxide film 3 is exposed out of the contact etch stop layer 43 by forming the trenches in the contact etch stop etch 43. Anisotropic dry etching is performed using a gas containing, for example, CF₄, C₄F₈, CH₂F₂, CHF₃ or CH₃F.

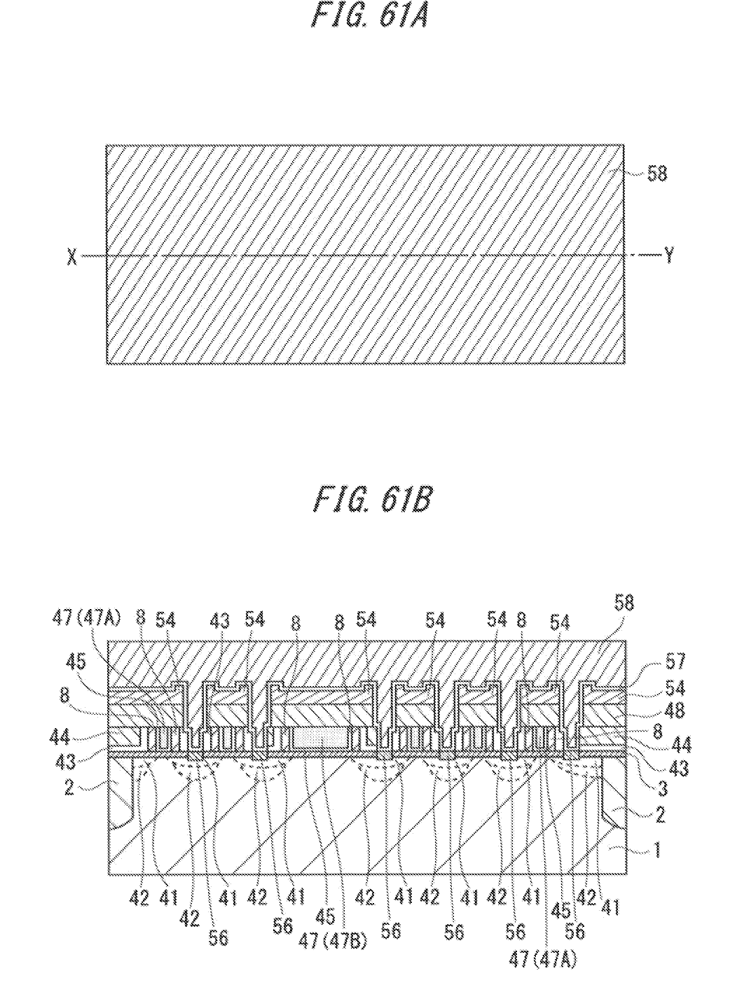

FIG. 61A is a plan view illustrating the manufacturing method of the semiconductor device according to the embodiment 2. FIG. 61B is a cross-sectional view illustrating the manufacturing method of the semiconductor device according to the embodiment 2, and represents a cross section along the single-dot chain line X-Y of FIG. 61A. In steps illustrated in FIGS. 61A and 61B, dry etching or solution treatment using HF or the like is performed to remove portions of the silicon dioxide film 3 exposed out of the contact etch stop layer 43. In the steps illustrated in FIGS. 61A and 61B, metal is deposited on surfaces of the semiconductor substrate 1 exposed out of the silicon dioxide film 3 and heat-treated to form silicides 56 on the surfaces of the semiconductor substrate 1. The metal deposited on the surfaces of the semiconductor substrate 1 is, for example, Ni, Co, Ti, Ru, W, Ta or the like. Each silicide 56 is, for example, WSi, TiSi, CoSi, NiSi, TaSi, RuSi or the like. In the steps illustrated in FIGS. 61A and 61B, barrier metal 57 is deposited and source-drain electrode metal 58 is buried and formed in the trenches formed in the interlayer insulating films 44 and 48 and the contact etch stop layer 43. The barrier metal 57 is, for example, Ti, TiN, Ru, Ta or the like. The source-drain electrode metal 58 is, for example, W, Cu, Al or the like. Alternatively, SiGe, Ge or the like may be buried in the surfaces of the semiconductor substrate 1 before the silicides 56 are formed in the surfaces of the semiconductor substrate 1, thereby forming semiconductor layers in the surfaces of the semiconductor substrate 1.

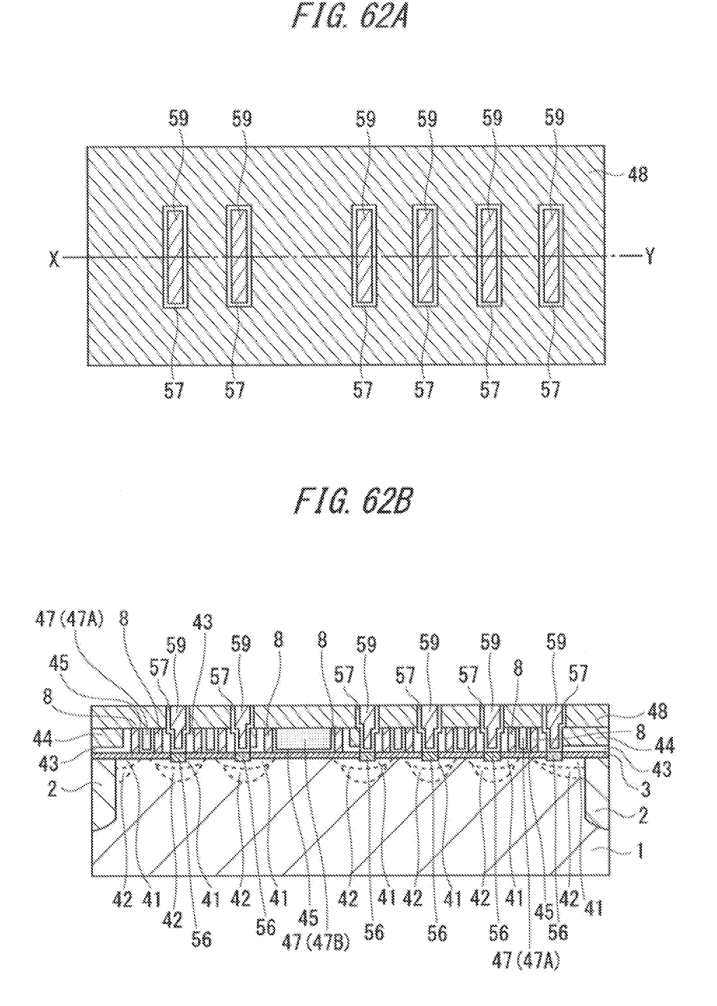

FIG. 62A is a plan view illustrating the manufacturing method of the semiconductor device according to the embodiment 2. FIG. 62B is a cross-sectional view illustrating the manufacturing method of the semiconductor device according to the embodiment 2, and represents a cross section along the single-dot chain line X-Y of FIG. 62A. In steps illustrated in FIGS. 62A and 62B, unneeded surfaces parts of the source-drain electrode metal 58 are removed by CMP to segmentalize the source-drain electrode metal 58, thereby forming a plurality of source-drain electrodes 59 on the semiconductor substrate 1. After wiring lines are formed on the interlayer insulating film 48, a desired back-end process is performed and thereby the semiconductor device is manufactured.

According to the manufacturing method of the semiconductor device in accordance with the embodiment 2, the plane-direction cross-sectional area of each source-drain electrode 59 included in the semiconductor device according to the embodiment 2 can be made larger, compared with the semiconductor device according to the embodiment 1.

The embodiments 1 and 2 described above may be modified in the manner to be described hereafter. Modified Examples 1 to 5 to be described below may be applied in combination to the semiconductor devices and the manufacturing methods thereof according to the embodiments 1 and 2.

### Modified Example 1

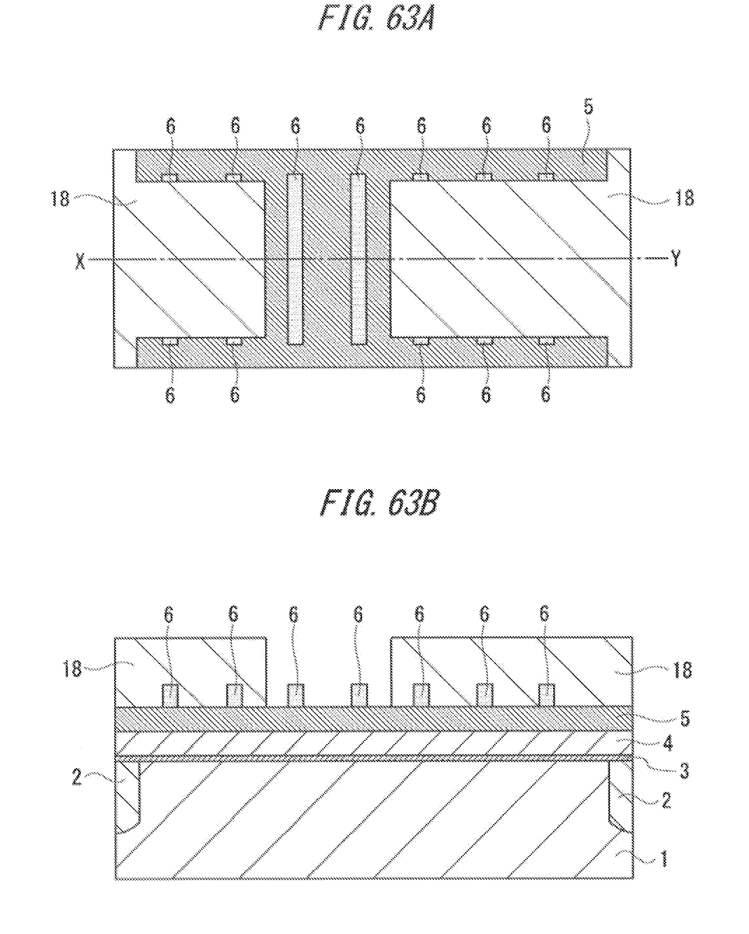

Modified Example 1 of the manufacturing methods of the semiconductor devices according to the embodiments 1 and 2 will be described with reference to FIGS. 63A to 66B. In Modified Example 1, steps illustrated in FIGS. 63A to 66B may be performed in substitution for the steps illustrated in FIGS. 6A to 12B.

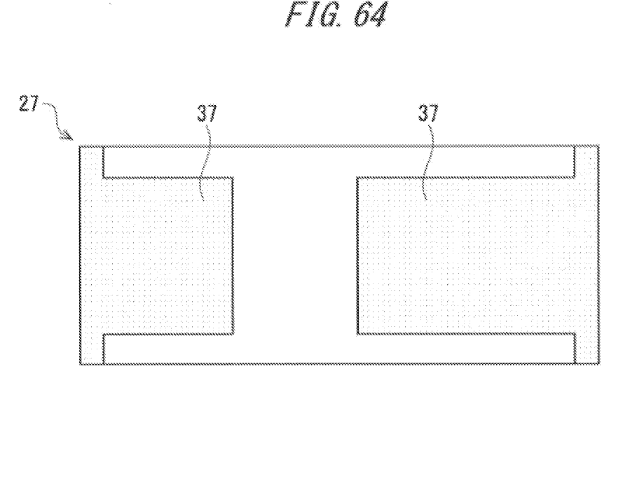

FIG. 63A is a plan view illustrating a manufacturing method of a semiconductor device according to Modified Example 1. FIG. 63B is a cross-sectional view illustrating the manufacturing method of the semiconductor device according to Modified Example 1, and represents a cross section along the single-dot chain line X-Y of FIG. 63A. Steps illustrated in FIGS. 63A and 63B follows after the same steps as those of the embodiment 1 illustrated in FIGS. 1A to 5B are performed. In the steps illustrated in FIGS. 63A and 63B, a resist is formed (coated) on a hard mask 5 above a semiconductor substrate 1, and then mask patterns 37 formed in a photomask 27 illustrated in FIG. 64 are exposure-transferred to the resist using an exposure apparatus. Note that an antireflection film may be formed between the resist and the hard mask 5. In the steps illustrated in FIGS. 63A and 63B, the resist to which the mask patterns 37 of the photomask 27 are transferred is developed to form resist patterns 18 on the hard mask 5 above the semiconductor substrate 1.

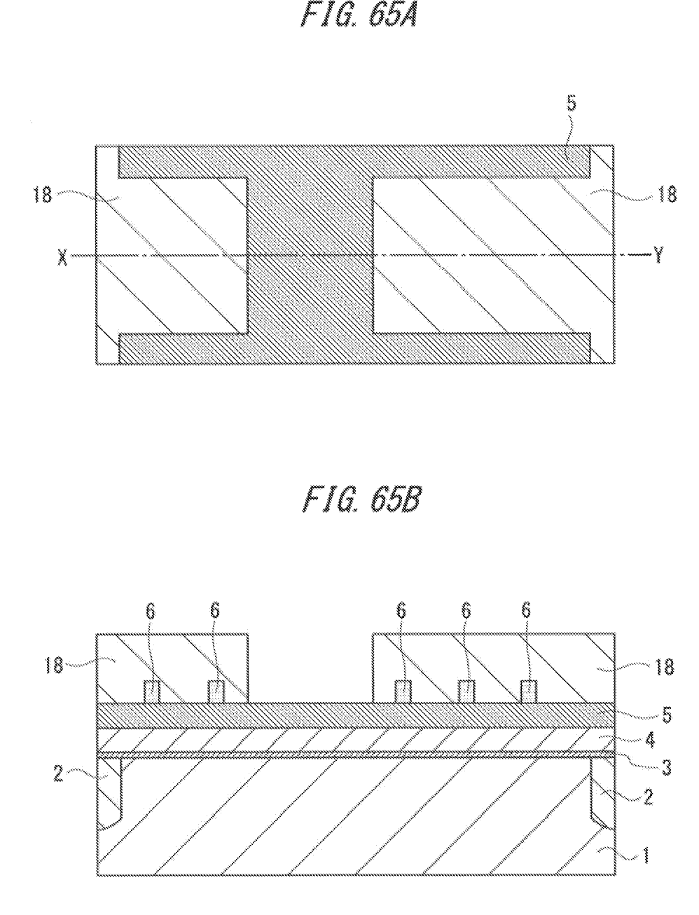

FIG. 65A is a plan view illustrating the manufacturing method of the semiconductor device according to Modified Example 1. FIG. 65B is a cross-sectional view illustrating the manufacturing method of the semiconductor device according to Modified Example 1, and represents a cross section along the single-dot chain line X-Y of FIG. 65A. In steps illustrated in FIGS. 65A and 65B, anisotropic dry etching is performed with the resist patterns 18 as a mask to remove hard masks 6 exposed out of places where the resist patterns 18 are opened. Consequently, both ends of each hard mask 6 are removed, thus reducing the long-side length of each hard mask 6. In addition, at least two adjacent hard masks 6 are removed. Anisotropic dry etching is performed using a gas containing, for example, CF₄, C₄F₈, CH₂F₂, CHF₃ or CH₃F.

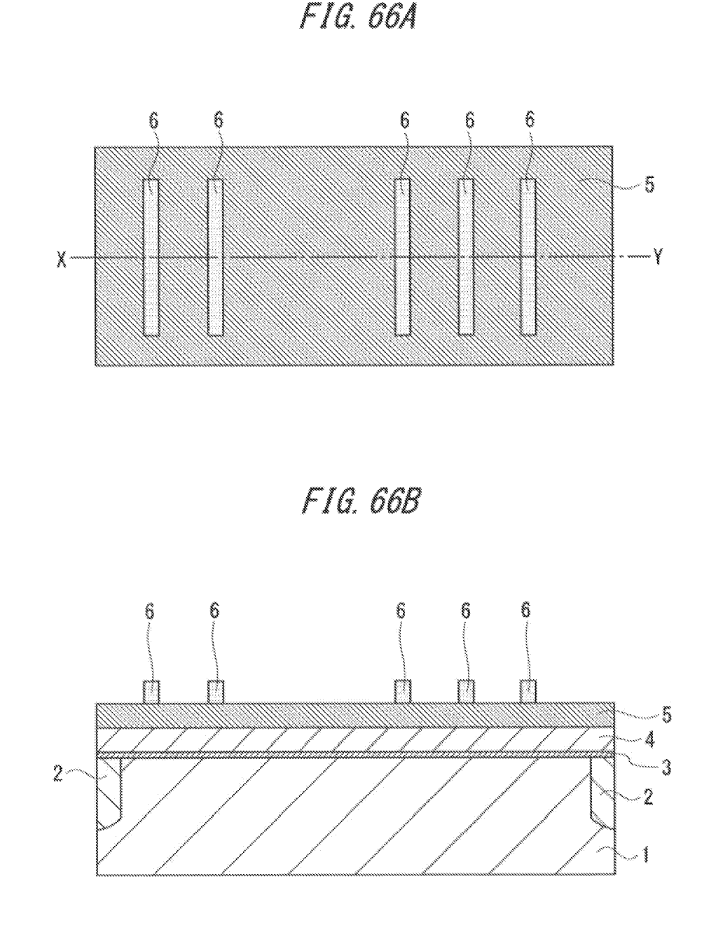

FIG. 66A is a plan view illustrating the manufacturing method of the semiconductor device according to Modified Example 1. FIG. 66B is a cross-sectional view illustrating the manufacturing method of the semiconductor device according to Modified Example 1, and represents a cross section along the single-dot chain line X-Y of FIG. 66A. In steps illustrated in FIGS. 66A and 66B, the resist patterns 18 are removed by, for example, ashing.

According to Modified Example 1, the long-side length of each hard mask 6 can be reduced and at least two adjacent hard masks 6 can be removed using one photomask 27. Consequently, according to Modified Example 1, it is possible to reduce the number of photolithography and etching steps, compared with the embodiments 1 and 2.

### Modified Example 2

A description will be made of Modified Example 2 of the manufacturing methods of the semiconductor devices according to the embodiments 1 and 2. In Modified Example 2, the steps of forming and processing the hard mask 5 in the manufacturing methods of the semiconductor devices according to the embodiments 1 and 2 may be omitted. That is, in Modified Example 2, the hard masks 6 may be formed on the dummy gates 4. According to Modified Example 2, it is possible to reduce the number of steps of forming and etching hard masks, compared with the embodiments 1 and 2. Note that in Modified Example 2, anisotropic etching is performed with the hard masks 6 and the resist pattern 14 as a mask to process the dummy gates 4 and form the dummy gates 4A and 4B.

### Modified Example 3

A description will be made of Modified Example 3 of the manufacturing methods of the semiconductor devices according to the embodiments 1 and 2. In Modified Example 3, the steps illustrated in FIGS. 10A to 13B may be omitted. That is, in Modified Example 3, the step of forming the resist pattern 13 and the etching step using the resist pattern 13 as a mask may be omitted. According to Modified Example 3, it is possible to reduce the number of resist pattern formation steps and the number of etching steps, compared with the embodiments 1 and 2. Note that in Modified Example 3, the resist pattern 14 may be formed so as to cover at least two adjacent hard masks 6 in the steps illustrated in FIGS. 14A and 14B.

### Modified Example 4

A description will be made of Modified Example 4 of the manufacturing methods of the semiconductor devices according to the embodiments 1 and 2. In Modified Example 4, the long-side length of each hard mask 53 may be reduced and at least two adjacent hard masks 53 may be removed using one photomask, as in Modified Example 1, in substitution for the steps illustrated in FIGS. 35A to 41B. Consequently, according to Modified Example 4, it is possible to reduce the number of photolithography and etching steps, compared with the embodiments 1 and 2.

### Modified Example 5

A description will be made of Modified Example 5 of the manufacturing methods of the semiconductor devices according to the embodiments 1 and 2. In Modified Example 5, the steps of forming and processing the hard mask 52 in the manufacturing methods of the semiconductor devices according to the embodiments 1 and 2 may be omitted. That is, in Modified Example 5, the hard mask 53 may be formed on the hard mask 51. According to Modified Example 5, it is possible to reduce the number of steps of forming and etching hard masks, compared with the embodiments 1 and 2. Note that in Modified Example 5, anisotropic etching is performed with the hard masks 53 as a mask to process the hard mask 51.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that the various changes, substitutions, and alterations could be made hereto without departing from the spirit and scope of the invention.

What is claimed is:

1. A manufacturing method of a semiconductor device, comprising:
forming a first resist film above a substrate;
placing a first photomask, that includes a first mask pattern, in a first position above the first resist film;
transferring the first mask pattern to the first resist film to form a first resist pattern above the substrate;
forming a second resist film above the substrate after forming the first resist pattern;
placing the first photomask in a second position above the second resist film; and
transferring the first mask pattern to the second resist film to form a second resist pattern above the substrate.

2. The manufacturing method of a semiconductor device according to claim 1, further comprising:
forming a third resist film above the substrate;
transferring a second mask pattern formed in a second photomask to the third resist film to form a third resist pattern above the substrate,
wherein the first resist pattern includes a plurality of first patterns,
the third resist pattern includes a third pattern that has a width larger than a width of each of the first pattern, and
the third resist pattern is formed so that positions where at least two first patterns, among the plurality of first patterns, are formed and a position where the third pattern is formed overlap with each other in a vertical direction of the substrate.

3. The manufacturing method of a semiconductor device according to claim 1, wherein the first resist pattern includes a plurality of first patterns,
the second resist pattern includes a plurality of second patterns, and
a position where each of the plurality of second patterns is formed is located between positions where adjacent first patterns, among the plurality of first patterns, are formed.
